(19) United States
(12) Patent Application Publication
(10) Pub. No.: US 2009/0063930 A1
(43) Pub. Date: Mar. 5, 2009

(54) CHECK MATRIX GENERATING METHOD, ENCODING METHOD, DECODING METHOD, COMMUNICATION DEVICE, ENCODER, AND DECODER

(75) Inventors: Wataru Matsumoto, Tokyo (JP); Rui Sakai, Tokyo (JP); Hideo Yoshida, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, TOKYO (JP)

(21) Appl. No.: 12/278,185

(22) PCT Filed: Jan. 31, 2007
(86) PCT No.: PCT/JP07/51551

§ 371 Date: Aug. 4, 2008

(30) Foreign Application Priority Data
Feb. 2, 2006 (JP) 2006-026310

(51) Int. Cl. H03M 13/03; G06F 11/10

(52) U.S. Cl. 714/752; 714/E11.032

(57) ABSTRACT

A regular quasi-cyclic matrix is generated with cyclic permutation matrices and specific regularity given to the cyclic permutation matrices. A mask matrix for making the regular quasi-cyclic matrix into an irregular quasi-cyclic matrix is generated. An irregular masked quasi-cyclic matrix is generated by converting a specific cyclic permutation matrix in the regular quasi-cyclic matrix into a zero-matrix using a mask matrix supporting a specific encoding rate. An irregular parity check matrix with an LDGM structure is generated with a masked quasi-cyclic matrix and a matrix in which the cyclic permutation matrices are arranged in a staircase manner.

### TECHNICAL FIELD

The present invention relates to an encoding technology in digital communications, in particular to a check-matrix generating method of generating an LDPC (parity check matrix for low-density parity check) code, an encoding method of encoding predetermined data bits using the parity check matrix, and a communication apparatus.

### BACKGROUND ART

Hereinafter, a conventional communication system that employs an LDPC code as an encoding system will be explained. Here, a case in which quasi-cyclic (QC) codes (see Non-patent Document 1) are employed as an example of the LDPC codes will be explained.

First, a flow of encoding/decoding processing in the conventional communication system that employs the LDPC codes as the encoding system will be explained briefly.

An LDPC encoder in a communication apparatus on a transmission-side (it is called a transmission apparatus) generates a parity check matrix H by a conventional method that will be explained below. Further, the LDPC encoder generates, for example, a generator matrix G with K-row×N-column (K: data length, N: code length). Note that when the parity check matrix for LDPC is defined as H (M-row×N-column), the generator matrix G will be a matrix that satisfies GH^{T}=0 (T is a transposed matrix).

Thereafter, the LDPC encoder receives messages (m₁, m₂, . . . , m_{K}) with the data length K to generate a code C as represented by following Equation (1) using these messages and the generator matrix G, where H (c₁, c₂, c_{N})^{T}=0.

$$\begin{matrix}C = ( {m}_{1} , {m}_{2} , … , {m}_{K} ) G \\ = ( {c}_{1} , {c}_{2} , … , {c}_{N} )\end{matrix} \qquad ( 1 )$$

A modulator in the transmission apparatus then performs digital modulation to the code C generated by the LDPC encoder according to a predetermined modulation system, such as BPSK (binary phase shift keying), QPSK (quadrature phase shift keying), multi-value QAM (quadrature amplitude modulation), and transmits a modulated signal x=(x₁, x₂, . . . x_{N}) to a reception apparatus.

Meanwhile, in a communication apparatus on a reception-side (which is called a reception apparatus), a demodulator performs digital demodulation to a received modulated signal y=(y₁, y₂, . . . y_{N}) according to the modulation system such as BPSK, QPSK, multi-value QAM, or the like, and an LDPC decoder in the reception apparatus further performs repetition decoding to demodulated results based on a “sum-product algorithm” to thereby output the decoded results (corresponding to the original messages m₁, m₂, . . . , m_{K}).

The conventional parity check-matrix generating method for the LDPC codes will now be explained concretely. As the parity check matrix for the LDPC codes, a following parity check matrix of QC codes is proposed, for example, in following Non-patent Document 1 (see FIG. 19). The parity check matrix of the QC codes shown in FIG. 19 is a matrix in which cyclic permutation matrices (P=5) with 5-row×5-column are arranged in a vertical direction (J=3) and in a horizontal direction (L=5).

Generally, a parity check matrix H_{QC} of the (J, L) QC codes with M (=pJ) rows×N (=pL) columns can be defined as following Equation (2). Incidentally, p is an odd prime number (other than 2), L is the number of cyclic permutation matrices in the parity check matrix HQ, in a transverse direction (column direction), and J is the number of cyclic permutation matrices in the parity check matrix H_{QC} in a longitudinal direction (row direction). [Numerical Expression 1]

$${H}_{QC} = [ \begin{matrix}I ( {p}_{0 , 0} ) & I ( {p}_{0 , 1} ) & ⋮ & I ( {p}_{0 , L - 1} ) \\ I ( {p}_{1 , 0} ) & I ( {p}_{1 , 1} ) & ⋮ & I ( {p}_{1 , L - 1} ) \\ ⋮ & ⋮ & ⋱ & ⋮ \\ I ( {p}_{J - 1 , 0} ) & I ( {p}_{J - 1 , 1} ) & ⋮ & I ( {p}_{J - 1 , L - 1} )\end{matrix} ] \\ Example \text{:} p = 5 , I ( 0 ) = [ \begin{matrix}1 & 0 & 0 & 0 & 0 \\ 0 & 1 & 0 & 0 & 0 \\ 0 & 0 & 1 & 0 & 0 \\ 0 & 0 & 0 & 1 & 0 \\ 0 & 0 & 0 & 0 & 1\end{matrix} ] \qquad ( 2 )$$

Where, in 0≦j≦J−1 and 0≦l≦L−1, I(p_{j,l}) are cyclic permutation matrices in which positions of a row index: r (0≦r≦P−1), and a column index: “(r+p_{j,l})mod p” are “1”, and other positions are “0”.

In addition, when the LDPC codes are designed, performance degradation generally occurs when there are many loops with a short length, and thus it is necessary to increase an internal diameter and to reduce the number of loops with the short length (loop 4, loop 6, or the like).

Incidentally, FIG. 20 is a schematic diagram illustrating an example of the check matrix represented by a Tanner graph, wherein in the binary parity check matrix H of {0,1} with M-row×N-column, nodes corresponding to each column are called bit nodes bₙ (1≦n≦N) (corresponding to circles in the figure), and nodes corresponding to each row are called check nodes cₘ (1≦m≦) (corresponding to rectangles in the figure), and further, when there is “1” at an intersection of the row and the column of the check matrix, a bipartite graph in which the bit nodes and the check nodes are connected with branches is called the Tanner graph. In addition, the loop represents a closed loop that starts from a specific node (corresponding to circles and rectangles in the figure) and ends at that node as shown in FIG. 20, and the internal diameter means the minimum loop thereof. Moreover, a loop length is represented by the number of branches constituting the closed loop, and is simply represented as loop 4, loop 6, loop 8, . . . according to the length.

Meanwhile, in following Non-patent Document 1, a range of an internal diameter g in the parity check matrix H_{QC} of (J,L) QC-LDPC codes is given by “4≦g≦12 (where g is an even number)”. However, it is easy to avoid g=4 and, and it results in g≧6 in many cases.

Non-patent Document 1: M. Fossorier, “Quasi-Cyclic Low Density Parity Check Code”, ISIT2003, p. 150, Japan, Jun. 29-Jul. 4, 2003.

### DISCLOSURE OF INVENTION

### Problem to be Solved by the Invention

According to the conventional technology, however, a plurality of totally different check matrices is required to change encoding rates, so that there are problems that a memory amount is increased and a circuit becomes complicated.

The present invention has been made to solve the above-mentioned problems, and it is an object of the present invention to obtain a communication apparatus capable of generating an irregular (weights of a row and a column are nonuniform) parity check matrix for LDPC codes that can deal with a wide range of encoding rates, and also capable of reducing the circuit scale as compared with the conventional technology.

### Means for Solving Problem

To solve the above problems and to achieve the object, a check-matrix generating method according to the present invention is for generating a parity check matrix for an LDPC (low-density parity check) code. The check-matrix generating method includes a quasi-cyclic matrix generating step of generating a regular (weights of a row and a column are uniform) quasi-cyclic matrix in which cyclic permutation matrices are arranged in a row direction and a column direction and specific regularity is given to the cyclic permutation matrices; a mask-matrix generating step of generating a mask matrix capable of supporting a plurality of encoding rates, for making the regular quasi-cyclic matrix into irregular (weights of a row and a column are nonuniform); a masking step of converting a specific cyclic permutation matrix in the regular quasi-cyclic matrix into a zero-matrix using a mask matrix corresponding to a specific encoding rate to generate an irregular masking quasi-cyclic matrix; and a check-matrix generating step of generating an irregular parity check matrix with an LDGM (low-density generation matrix) structure in which the masking quasi-cyclic matrix and a matrix in which the cyclic permutation matrices are arranged in a staircase manner are arranged in a predetermined location. In the regular quasi-cyclic matrix, a specific regularity of “p_{j,l}=(((p_{A}−p_{0,1}) (j+1))mod p_{A}) mod p” is provided to p_{j,l} of cyclic permutation matrices I(p_{j,l}) with p-row×p-column arranged at a row index j (0≦j≦J−1) and a column index 1 (0≦l≦L−1) (I(p_{j,l}) are cyclic permutation matrices in which positions of a row index: r (0≦r≦p−1) and a column index: “(r+p_{j,l})mod p” are “1” and other positions are “0”).

### EFFECT OF THE INVENTION

According to the present invention, there is an effect that it is possible to generate an irregular check matrix for the LDPC codes capable of dealing with a wide range of encoding rates.

### BRIEF DESCRIPTION OF DRAWINGS

FIG. 1 is a schematic diagram illustrating a configuration example of a communication system including an LDPC encoder and an LDPC decoder.

FIG. 2A is a schematic diagram illustrating a configuration of a product-sum operation unit in code generation.

FIG. 2B is a schematic diagram illustrating a configuration example of a code generating unit using the product-sum operation unit shown in FIG. 2A.

FIG. 3 is a schematic diagram illustrating a configuration example of an irregular parity check matrix H_{M} after being masked by a mask matrix Z.

FIG. 4 is a graph showing a result of comparing performances between code configuration methods.

FIG. 5 is a schematic diagram illustrating a code configuration method according to a first embodiment.

FIG. 6 is a schematic diagram illustrating a code when the lowest encoding rate prepared by a system is R₀=⅕.

FIG. 7 is a schematic diagram illustrating an example of a code configuration method according to the first embodiment.

FIG. 8 is a schematic diagram illustrating an example of a code configuration method according to a second embodiment.

FIG. 9 is a schematic diagram illustrating an example of a code configuration method according to a third embodiment.

FIG. 10 is a schematic diagram illustrating an example of a code configuration method according to a fourth embodiment.

FIG. 11 is a schematic diagram illustrating a configuration example of an LDPC decoder.

FIG. 12 is a schematic diagram illustrating an example of quasi-cyclic codes.

FIG. 13 is a schematic diagram illustrating parallelizing processing of irregular QC-LDPC codes.

FIG. 14 is a schematic diagram illustrating an example of a known parity check matrix.

FIG. 15 is a schematic diagram illustrating processing of forming LDPC codes corresponding to a plurality of encoding rates.

FIG. 16 is a schematic diagram illustrating an example of a parity check matrix of an encoding rate ⅓.

FIG. 17 is a schematic diagram illustrating an example of a parity check matrix of an encoding rate 1/3.

FIG. 18 is a schematic diagram illustrating a configuration example when encoding processing/decoding processing according to the present invention to a mobile communications system.

FIG. 19 is a schematic diagram illustrating an example of a parity check matrix of QC codes.

FIG. 20 is a schematic diagram illustrating a case in which an example of the check matrix is represented by a Tanner graph.

### EXPLANATIONS OF LETTERS OR NUMERALS

1: LDPC encoder
2: Modulator
3: Communication channel
4: Demodulator
5: LDPC decoder
51: Product-sum operation unit

### BEST MODE(S) FOR CARRYING OUT THE INVENTION

Hereinafter, embodiments of a check-matrix generating method according to the present invention will be explained in detail based on the drawings. Incidentally, the present invention is not limited by these embodiments.

### First Embodiment

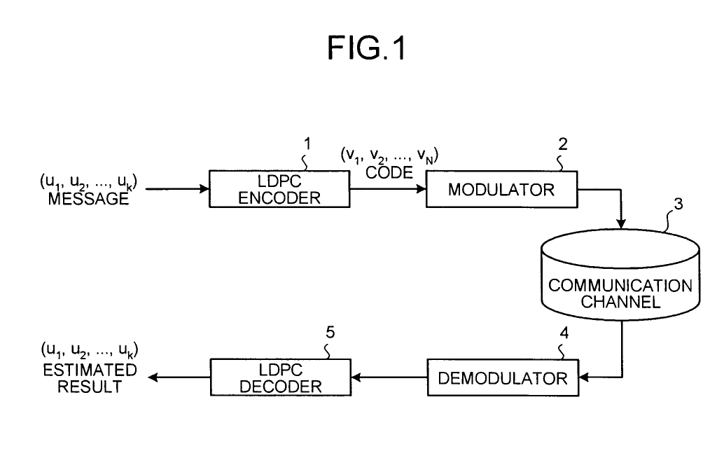

FIG. 1 is a schematic diagram illustrating a configuration example of a communication system including an LDPC encoder and an LDPC decoder according to the present embodiment. In FIG. 1, a communication apparatus (which is called a transmission apparatus) on a transmission-side has a configuration including an LDPC encoder 1 and a modulator 2, and a communication apparatus (which is called a reception apparatus) on a reception-side has a configuration including a demodulator 4 and an LDPC decoder 5.

Here, a flow of encoding processing and decoding processing in the communication system that employs LDPC codes will be explained briefly.

The LDPC encoder 1 in the transmission apparatus generates a parity check matrix generated by a check-matrix generating method according to the present embodiment, namely, a parity check matrix H_{M} with M-row×N-column to which masking processing is performed based on a predetermined masking rule described below.

Thereafter, the LDPC encoder 1 receives a message (u₁, u₂, . . . , u_{K}) with data length K to generate a code v with a length N using this message and the parity check matrix H_{M} as represented by following Equation (3). It should be noted that in the present embodiment, the encoding processing of data bits is performed without using the generator matrix G (K: data length, N: code length) calculated in the conventional technology.

v={(v₁,v₂, . . . , v_{N})εGF(2)(v₁,v₂, . . . , v_{N})H_{M}^{T}=0} (3)

The modulator 2 in the transmission apparatus then digital-modulates the code v generated by the LDPC encoder 1 according to a predetermined modulation system, such as BPSK, QPSK, and multi-value QAM, and transmits the modulated signal x=(x₁, x₂, . . . , x_{N}) to the reception apparatus to a communication channel 3.

Meanwhile, in the reception apparatus, the demodulator 4 digital-demodulates a modulated signal y=(y₁, y₂, . . . , y_{N}) received via the communication channel 3 according to a modulation system, such as the BPSK, QPSK, and multi-value QAM, and the LDPC decoder 5 in the reception apparatus further performs repetition decoding with a well-known decoding algorithm to thereby output the decoded result (corresponding to the original message u₁, u₂, . . . , u_{K})

Subsequently, the check-matrix generating method according to the present embodiment will be explained in detail. Incidentally, in the present embodiment, it is supposed that an irregular (weight distribution is nonuniform) parity check matrix is generated, and it is premised that an LDGM (low-density generation matrix) structure is employed as the structure. Moreover, check matrix generation processing of each embodiment explained hereinafter may be performed by the LDPC encoder 1 in the communication apparatus, or may be performed in advance outside the communication apparatus. When it is performed outside the communication apparatus, the generated check matrix is stored in an internal memory.

First, a parity check matrix H_{QCL} of QC-LDPC codes with the LDGM structure, which is a premise for the irregular parity check matrix H_{M} after the masking processing and is generated by the check matrix generation processing of the present embodiment, will be defined.

For example, the parity check matrix H_{QCL} (=[h_{m,n}]) of the QC-LDPC codes with the LDGM structure of M (=pJ) rows×N (=pL+pJ) columns can be defined as following Equation (4-1).

$$\begin{matrix}[ Numerical Expression 2 \text{-} 1 ] & \\ {H}_{QCL} := [ \begin{matrix}I ( {p}_{0 , 0} ) & I ( {p}_{0 , 1} ) & … & I ( {p}_{0 , L - 1} ) & I ( 0 ) & 0 & … & … & … & … & … & 0 \\ I ( {p}_{1 , 0} ) & I ( {p}_{1 , 2} ) & … & I ( {p}_{1 , L - 1} ) & I ( 0 ) & I ( 0 ) & 0 & ⋱ & ⋱ & ⋱ & ⋱ & ⋮ \\ ⋮ & ⋮ & ⋮ & ⋮ & 0 & ⋱ & ⋱ & ⋱ & ⋱ & ⋱ & ⋱ & ⋮ \\ I ( {p}_{J / 2 - 1 , 0} ) & I ( {p}_{J / 2 - 1 , 2} ) & … & I ( {p}_{J / 2 - 1 , L - 1} ) & ⋮ & ⋱ & I ( 0 ) & I ( 0 ) & 0 & ⋱ & ⋱ & ⋮ \\ ⋮ & ⋮ & ⋮ & ⋮ & I ( 0 ) & 0 & … & 0 & I ( 0 ) & 0 & ⋱ & ⋮ \\ ⋮ & ⋮ & ⋮ & ⋮ & 0 & I ( 0 ) & 0 & ⋱ & ⋱ & I ( 0 ) & ⋱ & ⋮ \\ ⋮ & ⋮ & ⋮ & ⋮ & ⋮ & ⋱ & ⋱ & ⋱ & ⋱ & ⋱ & ⋱ & 0 \\ I ( {p}_{J - 1 , 0} ) & I ( {p}_{J - 1 , 2} ) & … & I ( {p}_{J - 1 , L - 1} ) & 0 & … & 0 & I ( 0 ) & 0 & … & 0 & I ( 0 )\end{matrix} ] & ( 4 \text{-} 1 )\end{matrix}$$

Here, h_{m,n} represents an element at a row index m and a column index n in the parity check matrix H_{QCL}. Additionally, in 0≦j≦J−1 and 0≦l≦L−1, I(p_{j,l}) are cyclic permutation matrices in which positions of a row index: r (0≦r≦p−1), and a column index: “(r+p_{j,l})mod p” are “1”, and other positions are “0”. For example, I (1) can be represented as following Equation (4-2).

$$\begin{matrix}[ Numerical Expression 2 \text{-} 2 ] & \\ I ( 1 ) = [ \begin{matrix}0 & 1 & 0 & … & 0 \\ 0 & 0 & 1 & … & 0 \\ … & … & … & … & … \\ 0 & 0 & 0 & … & 1 \\ 1 & 0 & 0 & … & 0\end{matrix} ] & ( 4 \text{-} 2 )\end{matrix}$$

In the parity check matrix H_{QCL}, a left-hand side matrix (a portion corresponding to data bits) is a quasi-cyclic matrix H_{QC} that is the same as the parity check matrix of QC codes shown by Equation (2), and a right-hand side matrix (a portion corresponding to parity bits) is a matrix H_{T} or H_{D} in which I (0) are arranged in a staircase manner as shown in following Equation (5-1) or Equation (5-2).

$$\begin{matrix}[ Numerical Expression 3 \text{-} 1 ] & \\ {H}_{T} := [ \begin{matrix}I ( 0 ) & 0 & … & … & … & … & … & 0 \\ I ( 0 ) & I ( 0 ) & 0 & ⋱ & ⋱ & ⋱ & ⋱ & ⋮ \\ 0 & ⋱ & ⋱ & ⋱ & ⋱ & ⋱ & ⋱ & ⋮ \\ ⋮ & ⋱ & I ( 0 ) & I ( 0 ) & 0 & ⋱ & ⋱ & ⋮ \\ I ( 0 ) & 0 & … & 0 & I ( 0 ) & 0 & ⋱ & ⋮ \\ 0 & I ( 0 ) & 0 & ⋱ & ⋱ & I ( 0 ) & ⋱ & ⋮ \\ ⋮ & ⋱ & ⋱ & ⋱ & ⋱ & ⋱ & ⋱ & 0 \\ 0 & … & 0 & I ( 0 ) & 0 & … & 0 & I ( 0 )\end{matrix} ] & ( 5 \text{-} 1 ) \\ [ Numerical Expression 3 \text{-} 2 ] & \\ {H}_{D} := [ \begin{matrix}I ( 0 ) & 0 & … & … & 0 \\ I ( 0 ) & I ( 0 ) & 0 & ⋱ & ⋮ \\ 0 & ⋱ & ⋱ & ⋱ & ⋮ \\ ⋮ & ⋱ & I ( 0 ) & I ( 0 ) & 0 \\ 0 & … & 0 & I ( 0 ) & I ( 0 )\end{matrix} ] & ( 5 \text{-} 2 )\end{matrix}$$

However, the cyclic permutation matrices used in the staircase structure are not necessarily limited to I (0), but may be a combination of arbitrary I (s|sε[0, p−1]).

Note that, the LDGM structure means a structure in which a part of the parity check matrix is formed into a lower triangular matrix as the matrix shown in Equation (4-1). Encoding can be achieved easily by using this structure without using the generator matrix G. For example, when the systematic code v is represented as following Equation (6), and the information message u=(u₁, u₂, . . . , u_{K}) is given, parity elements pₘ=(p₁, p₂, . . . , p_{M}) are generated so that “H_{QCL}·v^{T}=0” may be satisfied, namely as following Equation (7).

$$\begin{matrix}v = ( {v}_{1} , {v}_{2} , … {v}_{K} , {v}_{K + 1} , {v}_{K + 2} , … , {V}_{N} ) \\ = ( {u}_{1} , {u}_{2} , … {u}_{K} , {p}_{1} , {p}_{2} , … , {p}_{M} )\end{matrix} \qquad ( 6 )$$

where N=K+M.

$$\begin{matrix}[ Numerical Expression 4 ] & \\ {p}_{m} = {\sum }_{n = 1}^{K + m - 1} {v}_{n} {h}_{m , n} & ( 7 ) \\ 1 \leq m \leq M & \\ 1 \leq n \leq N & \end{matrix}$$

Further, in the present embodiment, a specific regularity is provided in the parity check matrix H_{QCL} Of the QC-LDPC codes with the LDGM structure defined as Equation (4-1). Specifically, in the quasi-cyclic matrix H_{QC} portion on the left-hand side of the parity check matrix H_{QCL}, if p_{0,1} is set to an arbitrary integer, a specific regularity is provided to p_{j,l} of the cyclic permutation matrices I(p_{j,l}) with p-row×p-column arranged at a row index j (=0, 1, 2, . . . J−1) and a column index l (=0, 1, 2, . . . L−1) so as to satisfy following Equation (8-1), following Equation (8-2), following Equation (8-3), or following Equation (8-4).

p_{j,l}=p_{0,1}(j+1)mod p (8-1)

p_{j,l}=(p_{0,1}(j+1)mod p_{A})mod p (8-2)

p_{j,l}=((p−p_{0,1})(j+1))mod p (8-3)

p_{j,l}=((p_{A}−p_{0,1}) (j+1))mod p_{A})mod p p_{A}=157 p: prime number (8-4)

Incidentally, since the Equation (8-1) and Equation (8-2) are functions of p_{0,1}, j, and p, there is a feature that if only positions of columns of “1” at a first row of the cyclic permutation matrices are determined, positions of “1” at other rows can also be determined through calculation. However, the data length is determined by k=p×L, and thus p needs to be changed when the data length is changed. Values of p_{j,l} at the second row and thereafter of the cyclic permutation matrices vary by the value of p, and the number of small loops thereby increases in a loop distribution, which may cause the performance to be degraded. For example, if the value of p is small, the number of small loops increases. Meanwhile, the Equation (8-3) and Equation (8-4) are functions of p_{0,1}, j, p, and p_{A}. The p_{A} may be an arbitrary value, however, determination is desirably made to obtain the most satisfactory performance upon MAX data length that is required by the system. The maximum value determined by dividing the MAX data length by a fixed value L is set to p_{A}, and the most excellent performance is thereby obtained. The Equation (8-3) and Equation (8-4) use p_{0,1} which is searched for so that the small loops are reduced to an amount as small as possible in P=p_{A} in the Equation (8-1) and Equation (8-2), and as a result of this, values of p_{j,l} at rows other than the first row are important to form small loops. Consequently, the Equation (8-3) and Equation (8-4) are equations in which the value of p_{j,l} in p=p_{A} is maintained as much as possible and p_{j,l} is changed only when p_{j,l} is p or more which is decided by the data length. In this case, p_{j,l} is only partially changed, and this has an effect of decreasing the probability of degradation. Further, “p_{A}=157” is a value when the data length K=p×L (L=36) is assumed to be around 5000 to 6000.

For example, if p_{A}=157 and L=36 using the Equation (8-4), an example of p_{0,1} can be represented as following Equation (9).

{p_{0,1},p_{0,2},p_{0,3},p_{0,4},p_{0,5},p_{0,6},p_{0,7},p_{0,8},p_{0,9},p_{0,10},p_{0,11},p_{0,12},p_{0,13},p_{0,14},p_{0,15},p_{0,16},p_{0,17},p_{0,18},p_{0,19},p_{0,20},p_{0,21},p_{0,22},p_{0,23},p_{0,24},p_{0,25},p_{0,26},p_{0,27},p_{0,28},p_{0,29},p_{0,30},p_{0,31},p_{0,32},p_{0,33},p_{0,34},p_{0,35},p_{0,36}}={11,8,73,16,143,48,143,150,31,38,22,115, 135,116,55,55,84,13,12,116,131,33,3,7,115,43, 11,2,11,17,1,31,15,7,2,54} (9)

Next, the mask processing for the parity check matrix H_{QCL} which is specific processing in the check-matrix generating method according to the present embodiment will be explained.

For example, when the left-hand side matrix shown in Equation (4-1) is represented by the quasi-cyclic matrix H_{QC} of J×L as shown in following Equation (10-1), and a mask matrix Z (=[z_{j,l}]) is defined as a matrix with J-row×L-column on GF (2), the matrix H_{MQC} after the mask processing can be represented as following Equation (10-2) if a predetermined rule described below is applied.

$$\begin{matrix}[ Numerical Expression 5 \text{-} 1 ] & \\ {H}_{QC} := [ \begin{matrix}I ( {p}_{0 , 0} ) & I ( {p}_{0 , 1} ) & … & I ( {p}_{0 , L - 1} ) \\ I ( {p}_{1 , 0} ) & I ( {p}_{1 , 1} ) & … & I ( {p}_{1 , L - 1} ) \\ ⋮ & ⋮ & ⋱ & ⋮ \\ I ( {p}_{J - 1 , 0} ) & I ( {p}_{J - 1 , 1} ) & … & I ( {p}_{J - 1 , L - 1} )\end{matrix} ] & ( 10 \text{-} 1 ) \\ [ Numerical Expression 5 \text{-} 2 ] & \\ {H}_{MQC} = Z {H}_{QC} = [ \begin{matrix}{z}_{0 , 0} I ( {p}_{0 , 0} ) & {z}_{0 , 1} I ( {p}_{0 , 1} ) & … & {z}_{0 , L - 1} I ( {p}_{0 , L - 1} ) \\ {z}_{1 , 0} I ( {p}_{1 , 0} ) & {z}_{1 , 1} I ( {p}_{1 , 1} ) & … & {z}_{1 , L - 1} I ( {p}_{1 , L - 1} ) \\ ⋮ & ⋮ & ⋱ & ⋮ \\ {z}_{J - 1 , 0} I ( {p}_{J - 1 , 0} ) & {z}_{J - 1 , 1} I ( {p}_{J - 1 , 1} ) & … & {z}_{J - 1 , L - 1} I ( {p}_{J - 1 , L - 1} )\end{matrix} ] & ( 10 \text{-} 2 ) \end{matrix}$$

Here, z_{j,l} I(p_{j,l}) in Equation (10-2) is defined as following Equation (11).

$$\begin{matrix}[ Numerical Expression 6 ] & \\ {z}_{j , l} I ( {p}_{j , l} ) = \{ \begin{matrix}I ( {p}_{j , l} ) & for {z}_{j , l} = 1 \\ 0 matrix & for {z}_{j , l} = 0\end{matrix} & ( 11 )\end{matrix}$$

The zero-matrix is a zero-matrix with p-row×p-column. Additionally, the matrix H_{MQC} is a matrix in which the quasi-cyclic matrix H_{QC} is masked with 0-elements of the mask matrix Z, and the weight distribution is nonuniform (irregular), while a distribution of the cyclic permutation matrices of the matrix H_{MQC} is the same as a degree distribution of the mask matrix Z.

Note that a weight distribution of the mask matrix Z when the weight distribution is nonuniform shall be determined by a predetermined density evolution method as known. For example, the mask matrix with 72-row×36-column can be represented as following Equation (12) based on a column degree distribution by the density evolution method.

$$[ Numerical Expression 7 ]$$

$$Z = [ \frac{{Z}^{A}}{{Z}^{A} ( 1 : 36 , 2 : 13 ) {0}_{36 \times 24}} ] \qquad ( 12 )$$

Further, the mask matrix Z^{A} is a matrix as shown in following Equation (13).

$$[ Numerical Expression 8 ]$$

$${Z}^{A} = [ \begin{matrix}101010000100000000100000000001000000 \\ 101001000000000100000000000100000010 \\ 010011000100000000000100000000001000 \\ 100101000000100000000000010000000000 \\ 011000100000000001000000001000000000 \\ 011001000000000100001000000000000000 \\ 001011000001000000000001000000100000 \\ 100010001100000000000000100000000010 \\ 010011000010000000000000001000000001 \\ 010100000000000100000000010000000100 \\ 000010000000000010000100000100010000 \\ 000100001000010000010000000000010000 \\ 000110000000001000000010000000010000 \\ 001010000000000001000010000000000000 \\ 000011000100000000010000000000100000 \\ 101000000000000010000010000000000000 \\ 101001000000000010100000000000001000 \\ 011000010000000010000000100001000000 \\ 001100000001000000010000000000000001 \\ 010000001000100000000001000000000000 \\ 000010000001000000000000000010000100 \\ 010100010000010000000000010000000000 \\ 100100000000100000000000000010100000 \\ 010011000010000000000000000010000000 \\ 101001000000000001000000100000000000 \\ 100100100000100000000100000000000000 \\ 100010010010000000010000000000000000 \\ 001100100000001000001000000001000000 \\ 010101000000001000100000000000000000 \\ 101000001000000100100000000000000000 \\ 100100100001000000000000001000001000 \\ 100100000000010000001000000000000100 \\ 011000010000000001001000000000000010 \\ 100010000000001000000000000100000000 \\ 010010000010000000000100000000010000 \\ 000001000000010000000001000000000001\end{matrix} ] \qquad ( 13 )$$

In addition, Z^{A}(1:36, 2:13) is submatrices of Z^{A} which indicates submatrices formed of the 1st row to 36th row and the 2nd row to 13th column.

Hence, the irregular parity check matrix H_{M} to be finally determined in the present embodiment can be represented as following Equation (14) using, for example, the mask matrix Z with 72-row×36-column, the quasi-cyclic matrix H_{QC} with 72 (row index j is 0 to 71)×36 (column index l is 0 to 35), and H_{T} of 72 (row index j is 0 to 71)×36 (column index l is 0 to 35).

$$\begin{matrix}{H}_{M} = [ Z \times {H}_{QC} \vert {H}_{T} ] \\ = [ {H}_{MQC} \vert {H}_{T} ]\end{matrix} \qquad ( 14 )$$

Namely, the parity check matrix H_{MQC} for generating the LDPC codes C is given by a design of the mask matrix Z and a value of the cyclic permutation matrix at the row index j=0 of the quasi-cyclic matrix H_{QC}.

Subsequently, an implementation example when the encoding is achieved using the regular parity check matrix H_{M} without using the generator matrix G will be shown hereinafter, and an operation thereof will be explained. Note herein that, the parity check matrix H_{QCL} of the QC-LDPC codes with the LDGM structure is considered as a matrix shown in following Equation (15-1).

$$[ Numerical Expression 9 \text{-} 1 ]$$

$${H}_{QCL} = [ \begin{matrix}I ( 0 ) & I ( 0 ) & I ( 0 ) & 0 & 0 \\ I ( 1 ) & I ( 2 ) & I ( 0 ) & I ( 0 ) & 0 \\ I ( 2 ) & I ( 4 ) & 0 & I ( 0 ) & I ( 0 )\end{matrix} ] , p = 5 \qquad ( 15 \text{-} 1 )$$

Meanwhile, the irregular parity check matrix H_{M} in which the matrix shown in Equation (15-1) is masked is defined as a matrix shown in following Equation (15-2).

$$[ Numerical Expression 9 \text{-} 2 ]$$

$${H}_{M} = [ \begin{matrix}I ( 0 ) & I ( 0 ) & I ( 0 ) & 0 & 0 \\ I ( 1 ) & 0 & I ( 0 ) & I ( 0 ) & 0 \\ 0 & I ( 4 ) & 0 & I ( 0 ) & I ( 0 )\end{matrix} ] \qquad ( 15 \text{-} 2 )$$

Additionally, the information message is defined as u=(u_{p,1} u_{p,2})=(01100 11001). Note that u_{p,1} is provided by dividing u for every p bits to then give numbers in an ascending order to 1.

Here, as processing in generating codes without using the generator matrix G, a product-sum operation of the matrix H_{MQC} after the mask processing for p rows and the information message u will be explained.

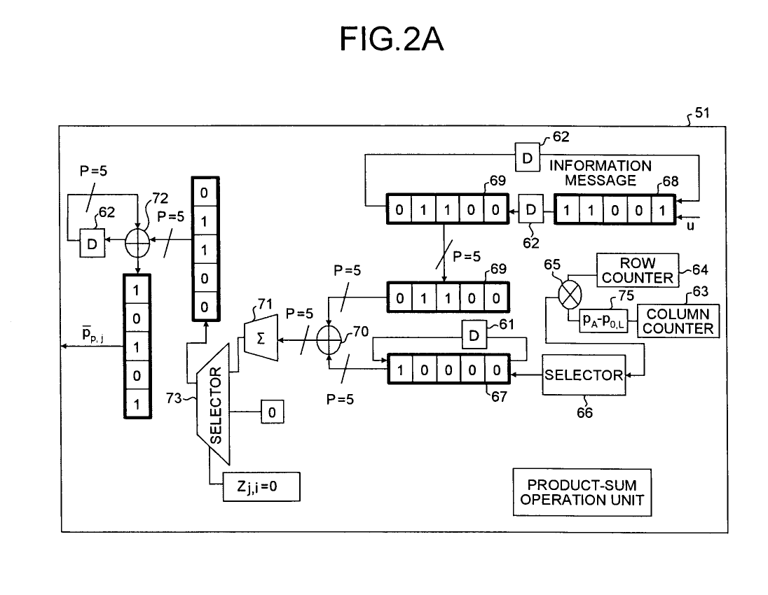

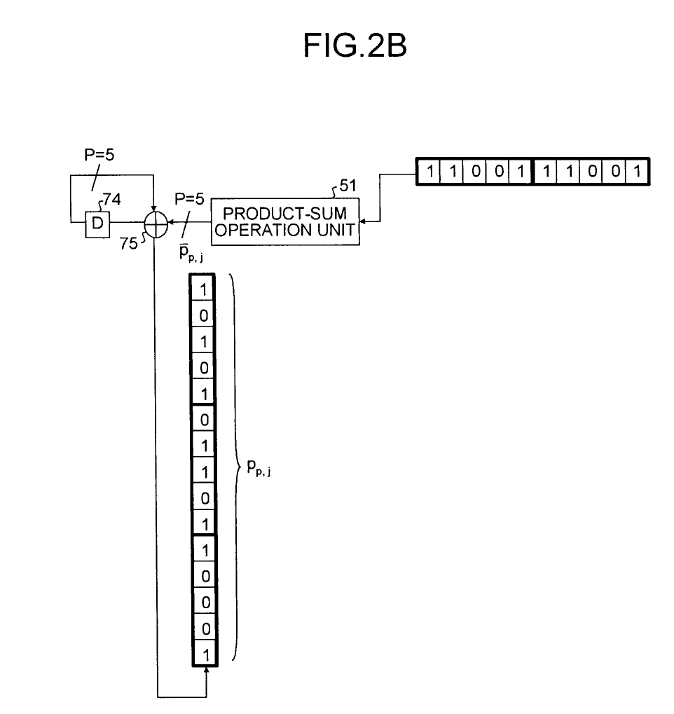

FIG. 2A is a schematic diagram illustrating a configuration of a product-sum operation unit 51 in code generation. Here, a reference clock is set to 1 clock, and in the figure, a delay element (D) 61 operates per 1 clock cycle, a delay element (D) 62 operates per p clock cycles (in this example, P=5). Additionally, a column counter 63 operates per p clock cycles, and a row counter 64 operates per L-p clock cycles (in this example, L=2).

In FIG. 2A, since the cyclic permutation matrix at the j-th row and l-th column of the quasi-cyclic matrix H_{QC} is I((((p_{A}−p_{0,1}) (j+1))mod p_{A})mod p), “0≦j≦J−1”, “≦l≦L−1”, and p_{A}=157, j is counted per L·p clock cycles in an ascending order by the row counter 64, “l+1” is counted per p clock cycles in an ascending order by the column counter 63, (p_{A}−p_{0,1}) is determined by a calculator 75, “(((p_{A}−p_{0,1}) (j+1))mod p_{A})mod p” is calculated by a multiplier 65, the calculated value is inputted into a selector 66, and a position of “1” of a register 67 with length p is decided, so that a position of “1” of the first row of the cyclic permutation matrix at the j-th row and l-th column is set.

Meanwhile, as for the information message u, it is divided for every p-length to be then inputted into registers 68 and 69 in order via the delay element 62 per p clock cycles. EXOR between the information message u with length p in the register 69, and a bit string in the register 67 is then calculated by the adder 70, and a summation of each bit of EXOR operation results is calculated by an adder 72. A sum-product calculation between the first row of I((((p_{A}−p_{0,1}) (j+1))mod p_{A})mod p) and u_{p,1} of the information message can be achieved by this processing. Next, the second row of I((((p_{A}−P_{0,1}) (j+1))mod p_{A})mod p) can be generated by shifting the register 67 using the delay element 61, thus a sum-product calculation between the second row of I((((p_{A}−p_{0,1}) (j+1))mod p_{A})mod p) and u_{p,l} of the information message can be achieved in a similar manner to the above. Thereafter, sum-product calculation results p_{p,j}′ for p rows of I((((p_{A}−p_{0,1}) (j+1))mod p_{A})mod p) can be obtained by repeatedly executing this processing p times. Incidentally, p_{p,j}′ means p bits of the sum-product calculation results of all the cyclic permutation matrices at the j-th row.

Next, to calculate the product-sum between I(((p_{A}−p_{0,1}) (j+1))mod p_{A}) mod p) and u_{p,1} from l=0 to l=L−1, the EXOR operation is repeatedly performed L times by the delay element 62 and the adder 72. This operation is repeatedly executed from j=0 to j=J−1, so that a sum-product calculation result p_{p,j}′ between the matrix H_{MQC} after the mask processing and u is obtained. Incidentally, in the selector 73, 0 is selectively outputted when z_{j,l}=0, and an output of an adder 71 is selectively outputted when z_{j,l}=1.

Meanwhile, FIG. 2B is a schematic diagram illustrating a configuration example of a code generating unit using the product-sum operation unit 51 shown in FIG. 2A. Here, a delay element (D) 74 operates per L-p clock cycles. In FIG. 2B, supposing that a sequence (parity bits) in which a number is given to j for every p bits in an ascending order is p_{p,j} the sequence p_{p,j} is obtained by the EXOR operation by the delay element 74 and an adder 75. Namely, “p_{p,j}=p_{p,j}′ p_{p,j-1}′” are calculated. Where, p_{p,0}′=0.

Note that the rule described in the previously applied “Japanese Patent Application 2005-367077” is applied to the masking rule when the quasi-cyclic matrix H_{QC} is masked with the 0-elements of the mask matrix Z.

Next, in the present embodiment, the code configuration method up to the encoding rate ⅕ will further be explained. The system configuration is the same as that of FIG. 1. Here, encoding of the encoding rate ⅕ or more is realized based on the content of “Japanese Patent Application 2005-367077”.

Specifically, the masking rule when the quasi-cyclic matrix H_{QC} with 144 (row index j is 0 to 143)×36 (column index l is 0 to 35) corresponding to the encoding rate ⅕ is masked with the 0-elements of the mask matrix Z is explained below. Here, the communication apparatus according to the present embodiment generates the mask matrix Z for making the quasi-cyclic matrix H_{QC} with 144×36 nonuniform (irregular) based on the regular masking rule.

Incidentally, the irregular parity check matrix H_{M} to be finally determined after the mask matrix Z is generated can be represented as following Equation (16) using, for example, the mask matrix Z with 144-row×36-column, the quasi-cyclic matrix H_{QC} with 144×36, and H_{T} of 144 (row index j is 0 to 143)×144 (column index l is 0 to 143).

$$\begin{matrix}{H}_{M} = [ Z \times {H}_{QC} \vert {H}_{T} ] \\ = [ {H}_{MQC} \vert {H}_{T} ]\end{matrix} \qquad ( 16 )$$

Further, H_{T} is defined as shown in following Equation (17), and T_{D} in H_{T} is defined as shown in following Equation (18).

### [Numerical Expression 10]

$${H}_{T} := [ \begin{matrix}{T}_{D} & 0 & 0 & 0 \\ I & I & 0 & 0 \\ 0 & I & I & 0 \\ 0 & 0 & I & I\end{matrix} ] \qquad ( 17 )$$

### [Numerical Expression 11]

$${T}_{D} := [ \begin{matrix}I ( 0 ) & 0 & 0 & ⋯ & 0 \\ I ( 0 ) & I ( 0 ) & 0 & ⋯ & 0 \\ 0 & I ( 0 ) & I ( 0 ) & ⋱ & ⋮ \\ ⋮ & ⋱ & ⋱ & ⋱ & ⋮ \\ 0 & ⋯ & 0 & I ( 0 ) & I ( 0 )\end{matrix} ] \qquad ( 18 )$$

Meanwhile, it is assumed that the irregular parity check matrix corresponding to the codes of the encoding rate ½ is “H_{M(1/2)=[}Z^{A}×H_{QC(1/2)}|H_{T(1/2)}]”. Note that Z^{A} (=Z^{A(1/2)}) is the mask matrix with 36-row×36-column, H_{QC(1/2)} represents the quasi-cyclic matrix of 36 (row index j is 0 to 35)×36 (column index l is 0 to 35) of ¼ from the top in the quasi-cyclic matrix H_{QC}, and H_{T(1/2)} is the T_{D}. Additionally, corresponding to the encoding rates ⅓, ¼, ⅕, the irregular parity check matrices are represented as H_{M(1/3)}, H_{M(1/4)}, H_{M(1/5)} (=H_{M}), the mask matrices are represented as Z^{A(1/3)}, Z^{A(1/4)}, Z^{A(1/5)} (=Z), the quasi-cyclic matrices are represented as H_{QC(1/3)}, H_{QC(1/4)}, H_{QC(1/5)} (=H_{QC}), and are represented as H_{T(1/3)}, H_{T(1/4)}, H_{T(1/5)} (=H_{T}), respectively.

For example, the mask matrix Z generated by the processing can be represented as following Equation (19).

$$[ Numerical Expression 12 ]$$

$${Z}_{1} = [ \begin{matrix}\underline{{Z}^{A}} \\ \underline{{Z}^{A} ( 1 : 36 , 2 : 13 ) {0}_{36 \times 24}} \\ \underline{{Z}^{A} ( 1 : 36 , 3 : 14 ) {0}_{36 \times 24}} \\ {Z}^{A} ( 1 : 36 , 4 : 15 ) {0}_{36 \times 24}\end{matrix} ] \qquad ( 19 )$$

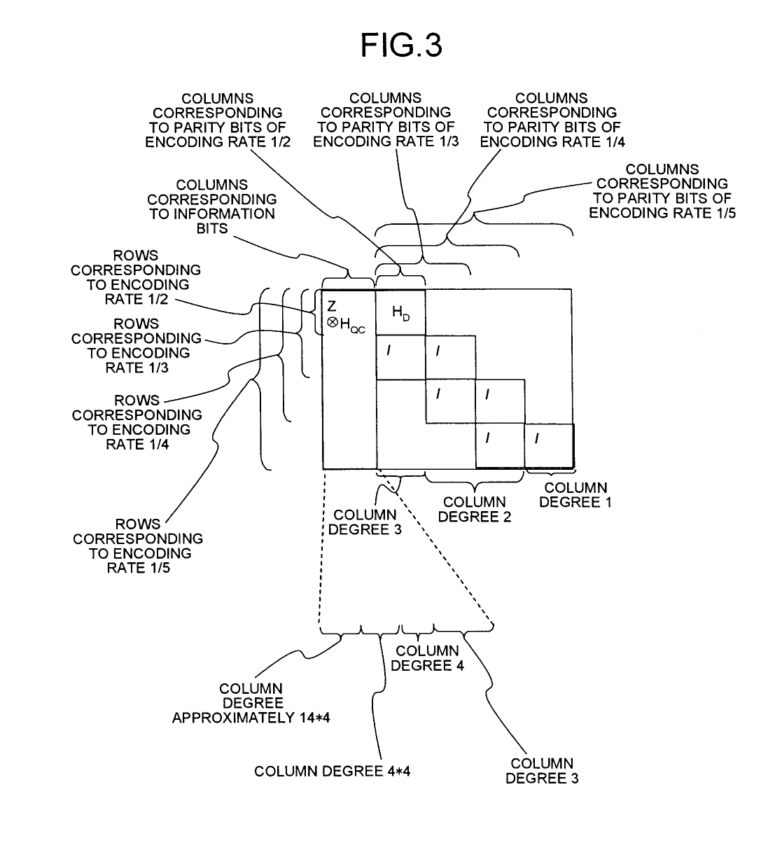

FIG. 3 is a view showing a configuration example of the irregular parity check matrix H_{M} after being masked by the mask matrix Z that is generated in the above manner.

As described above, since the mask matrix Z is composed only using the submatrices of the mask matrix Z^{A} corresponding to the encoding rate ½ in the present embodiment, the memory capacity for storing the mask matrix can be reduced even when the mask matrix becomes large according to the encoding rate.

Additionally, each mask matrix according to the encoding rate is used while shifting the submatrices of the mask matrix Z^{A} so that the same pattern may not be formed in a column direction. Specifically, the submatrices of the mask matrix Z^{A} are separated into submatrices with a heavy column degree (weight 14) and submatrices with light column degrees (weight is four or less), and are used while each of them is shifted. For example, Z^{A}(1:36,2:13) are the submatrices of Z^{A} in the mask matrix Z^{A}, whereas in the mask matrix Z^{A(1/3)}, they are shifted to the left per column, and Z^{A}(1:36,3:14) after the shift are coupled under Z^{A}(1:36,2:13) of the mask matrix Z^{A}. As for the mask matrices Z^{A(1/4)}, Z^{A(1/5)}, submatrices of the mask matrix Z^{A} are also used while being shifted so that the same pattern may not be formed in the column direction. Accordingly, small loops that are easy to be generated when H_{T} is used can be avoided.

Next, the case in which the LDPC codes corresponding to the encoding rates are configured using the irregular parity check matrix H_{M} will be explained below.

The lower limit of the encoding rate of the code generated by, for example, the code configuration method and defined by M and N is desirably set to any value from ⅓ to ⅙. To achieve any encoding rate equal to or less than the value, using repeated transmission which is explained later is better than using the code configuration method the same as the code configuration method when the encoding rate is ⅕ because an excellent performance is obtained.

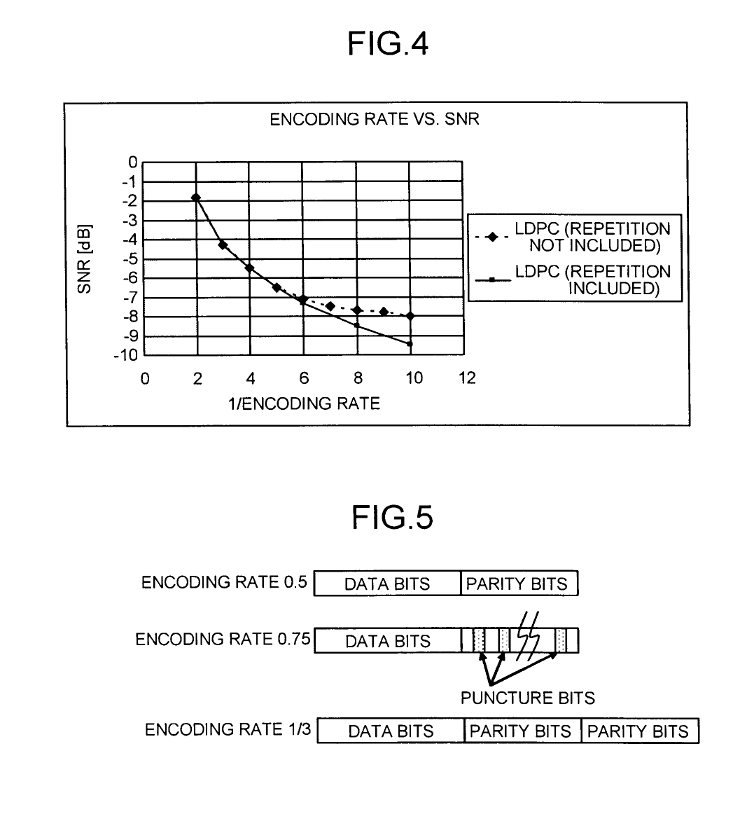

FIG. 4 is a graph showing a result of comparing performances between the case where the encoding rate up to 1/10 is prepared in the same method as the code configuration method when the encoding rate is ⅕, and a case where the repeated transmission of a code (the above-mentioned code is used when an encoding rate is up to ⅕, and the repeated transmission is used when an encoding rate is smaller than that). Here, it is understood that more excellent performance is obtained by using the repeated transmission. Note that the LDPC codes with data length of 1352 bits are used as the code in FIG. 4. The communication channel is AWGN, and modulation is assumed to use the BPSK.

FIG. 5 is a schematic diagram illustrating an example of the code configuration method according to the present embodiment, wherein for example, codes of the encoding rate 0.5 are defined as a reference code, and parity is punctured in generating a code of an encoding rate (=0.75) higher than that. Incidentally, for decoding at this time, it is only necessary to insert zero in a received LLR corresponding to puncturing bits using the check matrix of the encoding rate ½ to then perform a normal LDPC decoding. Meanwhile, parity is added in generating a code of an encoding rate (=⅓) lower than that. Decoding at this time is performed by using only the submatrices of the check matrix H_{M} corresponding to the encoding rate, as shown in FIG. 3.

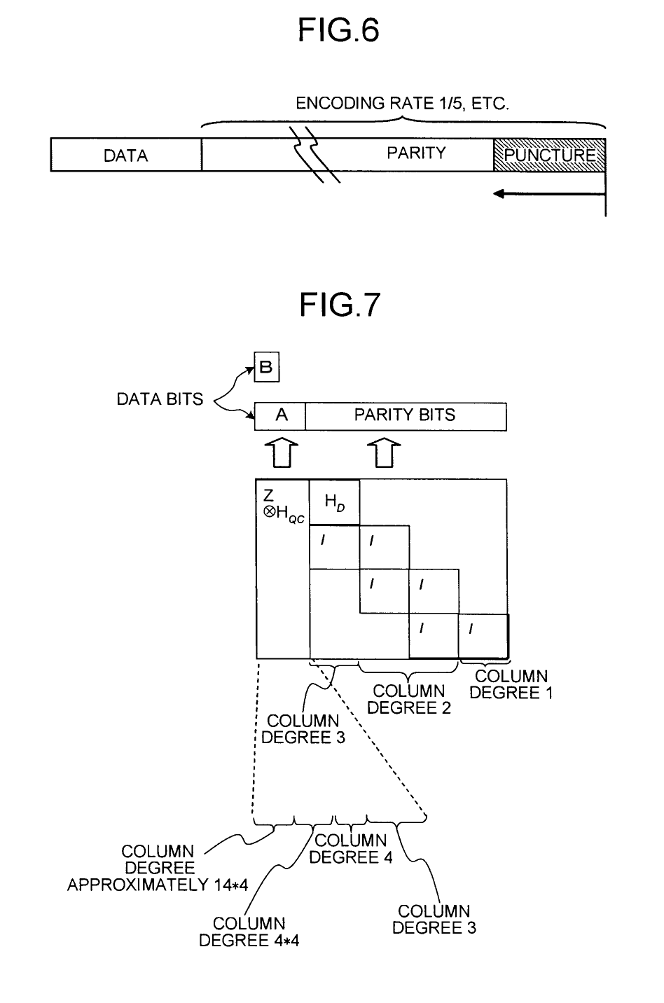

A configuration method of the LDPC codes corresponding to the encoding rates will be specifically explained here. For example, it is supposed that the lowest encoding rate prepared by the system is R₀=⅓ or less. FIG. 6 is a schematic diagram illustrating codes when the lowest encoding rate prepared by the system is, for example, R₀=⅕.

For example, when the codes corresponding to the encoding rate R₀=⅕ are stored in the memory to form codes of an encoding rate R₁, and if the encoding rate R₁ is less than ½, namely, if the encoding rate R₁ is any value between ½ to ⅕, the parity bits are punctured from the end of the code in order.

Meanwhile, for example, if an encoding rate of ⅕ or less is required, code bits B (length b: information for bits corresponding to each column is the same as A) selected in order of decreasing the column weight are added to a code (A+parity bits in FIG. 7) of an encoding rate K/N=⅕ based on the data length K and the code length N as shown in FIG. 7 in the present embodiment, to generate the code of an encoding rate K/(N+b). For example, if b=K, the encoding rate becomes ⅙, while if b=N, the encoding rate becomes 1/10. FIG. 7 is a schematic diagram illustrating the code configuration method according to the present embodiment when an encoding rate of ⅕ or less is required.

If the same code is repeatedly transmitted twice as b=N and an encoding rate lower than the rate is required, code bits with the number of bits corresponding to the low encoding rate selected in order of decreasing the column weight are transmitted again. Accordingly, it is also possible to achieve a lower encoding rate.

The code encoded by the method is then received by the reception apparatus through the communication channel, and if parts of or all of the code overlap when the decoder corrects an error, received values of the overlapped bits are added by the number of the overlapped portions and are averaged, to then transfer the result to the decoder. Moreover, it is known that the decoding performance becomes better when the code bits correspond to a column with a high weight. Thus, in the present embodiment, the variance of noise component can be reduced by the processing, and the reliability thereby increases (the error rate of the corresponding bits decreases), and thus improving the decoding performance.

Incidentally, it is described in the present embodiment that p of the cyclic permutation matrices is an odd prime number (other than 2), however, p is not limited thereto, and thus any odd number may be selected. In this case, although the performance may be degraded upon puncture of the high encoding rate, the degradation is only a slight amount. Meanwhile, if a prime number is used, it is necessary to obtain a table of prime numbers and previously store them therein to avoid an increase in the amount of calculations, however, if an odd number is used, the value does not need to be stored.

### Second Embodiment

Next, a code configuration method according to a second embodiment will be explained below. Here, processing different from that of the first embodiment will be explained.

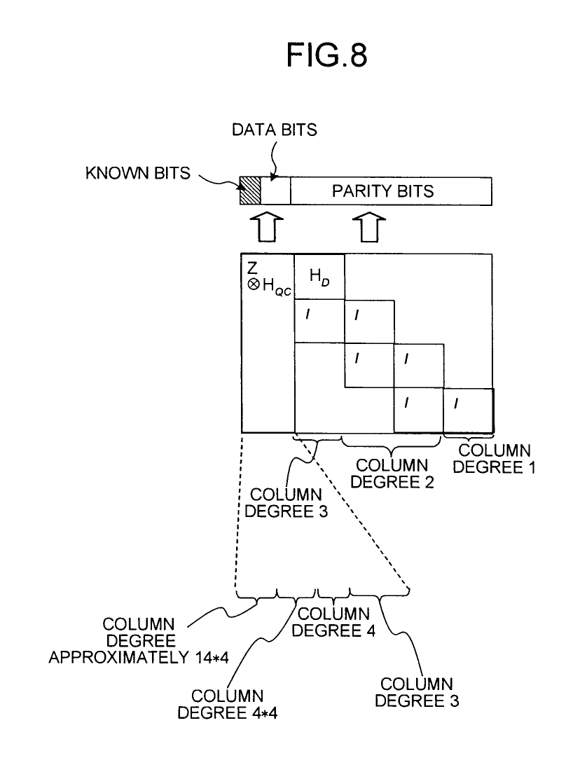

When p (an odd number or a prime number other than 2) of the cyclic permutation matrices in the parity check matrix for the LDPC codes is set to be variable, data length K=p×r (r is the number of unit matrices: r=36 in the first embodiment) can be set to be variable. Meanwhile, if the data length K cannot be represented by p×r, the code is formed as shown in FIG. 8.

For example, the LDPC encoder 1 selects an integer value obtained by rounding up K/r for p, sequentially inserts the known value “0” or “1” in bits corresponding to portions with the heavy column degree in the parity check matrix by the number of “(integer p obtained by rounding up K/r)×r−K”, and encodes them. The decoding side determines the known value “0” or “1” for the values corresponding to the same bits in the parity check matrix and decodes them.

This allows assignment of the most reliable known values (100% no error) to the bits corresponding to the heavy column degree, and thus the decoding performance can be improved.

When the irregular parity check matrix for the LDPC codes generated in the first embodiment is used to encode bits and a code with a code length N is generated, the code is also formed as shown in FIG. 8 to achieve an encoding rate equal to or less than the encoding rate (N−M)/N which is decided by the number of rows M and the number of columns N of the parity check matrix.

For example, similarly to the above, the known value “0” or “1” is inserted in bits in order of decreasing the column degree in the parity check matrix corresponding to the data bits, to be encoded. Accordingly, the code of the low encoding rate can be easily generated. The decoding side determines the known value “0” or “1” for the values corresponding to the same bits in the parity check matrix and decodes them.

This enables the codes of the low encoding rate to be purposely formed and the most reliable known values (100% no error) to be assigned to the bits corresponding to the heavy column degree, and thus excellent decoding performance can be obtained when the decoding performance of the bits corresponding to the heavy column degree greatly affects the overall decoding performance.

### Third Embodiment

Next, a code configuration method according to a third embodiment will be explained below. Here, processing different from the processing of the first and the second embodiments will be explained.

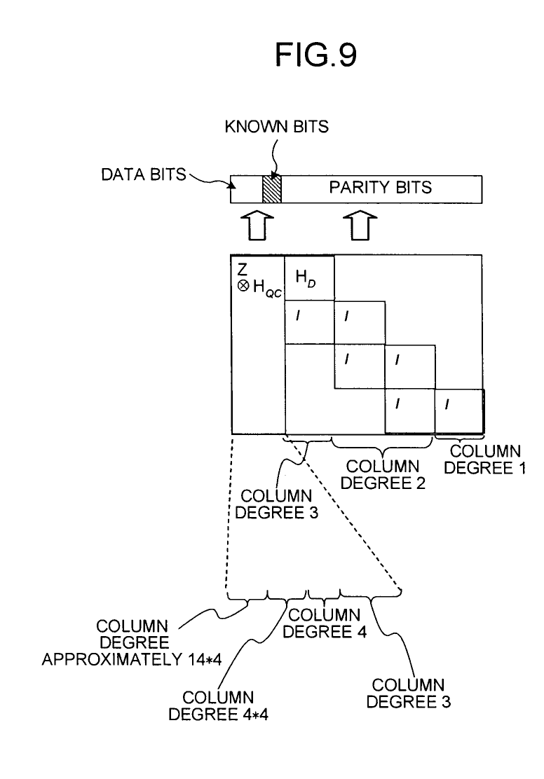

When p (an odd number or a prime number other than 2) of the cyclic permutation matrices in the parity check matrix for the LDPC codes generated in the first embodiment is set to be variable, data length K=p×r (r is the number of unit matrices: r=36 in the first embodiment) can be set to be variable. Meanwhile, if the data length K cannot be represented by p×r, the code is formed as shown in FIG. 9.

For example, the LDPC encoder 1 selects an integer value obtained by rounding up K/r for p, sequentially inserts the known value “0” or “1” in bits corresponding to portions with light column degrees of data bit portion (bit portion corresponding to columns in the matrix H_{MQC} after masking processing) in the check matrix by the number of “(integer p obtained by rounding up K/r)×r−K”, and encodes them. The decoding side determines the known value “0” or “1” for the values corresponding to the same bits in the parity check matrix and decodes them.

If the bits corresponding to the portions with light column degrees greatly affect an error distribution, or if a factor of degradation is caused by the portions with the light column degrees, the known value “0” or “1” is sequentially inserted in the bits corresponding to the portions with the light column degrees and the values are encoded, and this allows more improvement of the performance.

Additionally, when the irregular parity check matrix for the LDPC codes generated in the first embodiment is used to encode bits and a code with a code length N is generated, the code is also formed as shown in FIG. 9 to achieve an encoding rate equal to or less than the encoding rate (N−M)/N which is decided by the number of rows M and the number of columns N of the parity check matrix.

For example, similarly to the above, the known value “0” or “1” is inserted in bits in order of increasing the column degree in the parity check matrix corresponding to the data bits, to be encoded. Accordingly, the code of the low encoding rate can be easily generated. The decoding side determines the known value “0” or “1” for the values corresponding to the same bits in the parity check matrix and decodes them.

This enables the code of the low encoding rate to be purposely formed, and further, if the decoding performance of the bits corresponding to the light column degrees greatly affects the overall decoding performance, or even if the factor of degradation is caused by the portions with the light column degrees, the bits corresponding to the light column degrees can be determined by known data, and thus excellent decoding performance can be obtained.

### Fourth Embodiment

Next, a code configuration method according to a fourth embodiment will be explained below. Here, processing different from the processing of the first, the second, or the third embodiment will be explained.

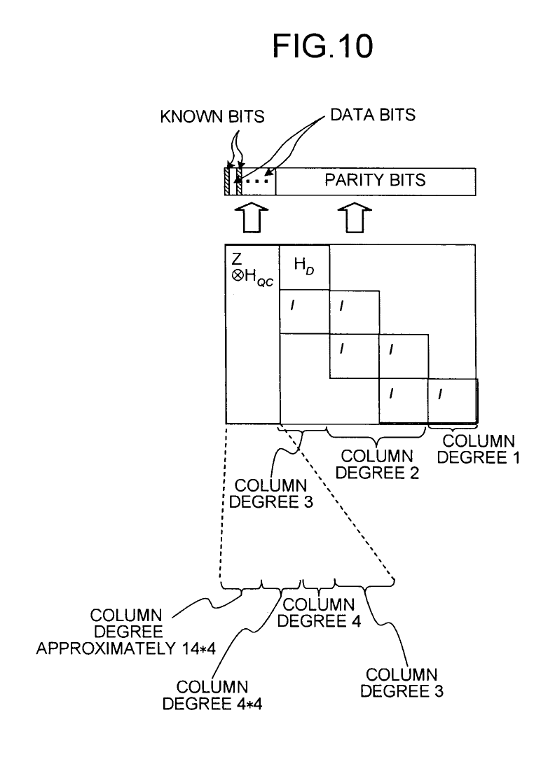

When p (an odd number or a prime number other than 2) of the cyclic permutation matrices in the parity check matrix for the LDPC codes generated in the first embodiment is set to be variable, the data length K=p×r (r is the number of unit matrices: r=36 in the first embodiment) can be set to be variable. Meanwhile, if the data length K cannot be represented by p×r, the code is formed as shown in FIG. 10.

For example, the LDPC encoder 1 selects an integer value obtained by rounding up K/r for p, inserts the known value “0” or “1” in data bit portion (bit portion corresponding to columns in the matrix H_{MQC} after masking processing) in the check matrix at approximately uniform intervals by the number of “(integer p obtained by rounding up K/r)×r−K”, and encodes them. The decoding side determines the known value “0” or “1” for the values corresponding to the same bits in the parity check matrix and decodes them.

If the factor of degradation is not caused by the heavy or the light column degree in the error distribution, better performance may be obtained in the way to insert the known value “0” or “1” in data bit portion (bit portion corresponding to columns in the matrix H_{MQC} after masking processing) in the check matrix at approximately uniform intervals, to be encoded.

Additionally, in the second embodiment, to prepare an encoding rate equal to or less than the encoding rate (N−M)/N which is decided by the number of rows M and the number of columns N of the parity check matrix, the known value is assigned to the bits corresponding to columns with the heavy column degree. However, if there are too many known values, this may cause performance degradation. Thus, the low encoding rate is achieved by the following method in the present embodiment.

For example, when the irregular parity check matrix for the LDPC codes is used to encode bits and a code with a code length N is generated, the code is also formed as shown in FIG. 10 to achieve an encoding rate equal to or less than the encoding rate (N−M)/N which is decided by the number of rows M and the number of columns N of the parity check matrix.

Specifically, similarly to the above, the known value “0” or “1” is inserted in data bit portion (bit portion corresponding to columns in the matrix H_{MQC} after masking processing) in the check matrix at approximately uniform intervals, to be encoded. Accordingly, the code of the low encoding rate can be easily generated. The decoding side determines the known value “0” or “1” for the values corresponding to the same bits in the parity check matrix and decodes them.

As an example, if the number of data bits is ½ of the number of columns corresponding to the data bits of a check matrix, an information sequence u′ inserted with the known value “0”, based on data bit sequence set to u={u₁, u₂, . . . , uₖ}, becomes u′={u₁, 0, u₂, 0, u₃, 0, . . . , uₖ, 0}. As described above, in the code of the encoding rate ⅕, the encoding rate becomes 1/10 by this operation. Additionally, if the number of data bits is ⅓ of the number of columns corresponding to the data bits in a check matrix, degradation may not sometimes occur even if the known number is large. In this manner, the present embodiment enables the code of the low encoding rate to be easily prepared and degradation to be minimized when the known number is large.

### Fifth Embodiment

In a fifth embodiment, decoding processing corresponding to the encoding processing using the irregular parity check matrix H_{M} generated in the first embodiment will be explained below.

The LDPC decoding according to the present embodiment is applicable to a case where calculation and updating of likelihood information (LLR) by the row processing and the column processing are performed per bit or per predetermined plural bits, and, for example, the repetition number of times is reduced by parallelizing operation processing. In the present embodiment, the “cyclic approximation min algorithm” using so-called “Overlapped” Bₘₙ^{C} and Sₘ, is executed, in which Bₘₙ₍ᵢ₎ and Sₘ in the intermediate-result storing unit are determined as a set regardless of the number of parallelization and all the parallelized processing units update the same Bₘₙ^{C} and Sₘ. Hereinafter, the decoding algorithm according to the present embodiment is called “Overlapped cyclic approximation min algorithm”.

Here, the “Overlapped cyclic approximation min algorithm” executed in the reception apparatus according to the present embodiment is shown below.

(Initialization Step)

First, the repetition number of times l=1 and the maximum repetition number of times lₘₐₓ are set. Moreover, initial LLR of the minimum k value at m-th row is set as βₘₙ₍ᵢ₎⁽⁰⁾, received LLR: λₙ is inputted, and Bₘₙ₍ᵢ₎^{C} is calculated as shown in following Equation (43). In addition, sgn(λₙ) is inputted as a code of initial LLR: βₘₙ⁽⁰⁾ at the m-th row and Sₘ is calculated as shown in following Equation (20).

$$[ Numerical Expression 13 ]$$

$${B}_{{mn}^{′}}^{C} = \vert {β}_{mn ( i )}^{( 0 )} \vert = {min}_{n ∈ N ( m ) \backslash \{ n ( 1 ) , n ( 2 ) , … , n ( i - 1 ) \}} [ \vert {λ}_{n} \vert ] , ∀ i ∈ [ 1 , k ] \\ {S}_{m} = {\prod }_{n ∈ N ( m )} sgn ( {λ}_{n} ) \\ n ( i ) = arg {min}_{n ∈ N ( m ) \backslash \{ n ( 1 ) , n ( 2 ) , … , n ( i - 1 ) \}} [ \vert {λ}_{n} \vert ] \\ n ( 0 ) = φ \qquad ( 20 )$$

Where, Bₘₙ₍ᵢ₎^{C} is the absolute value of LLR: βₘₙ₍ᵢ₎ of the minimum k value at the m-th row, which is commonly used in parallelizing processing. In addition, n(i) is the column index of minimum i-th LLR in Bₘₙ₍ᵢ₎^{C}.

(Row Processing Step)

Next, as the row processing step, LLR: αₘₙ⁽¹⁾ of l-th repetition of a bit n to be transmitted from a check node m to a bit node n is updated by following Equation (21) for 0≦g≦G−1, g·N_{G}+1≦n≦(g+1)·N_{G}, and each m. Here, G is the number of parallelization and N_{G} is the number of columns to be processed by each of parallelized decoding circuits. In addition, G·N_{g}=N. In the present embodiment, a starting column of each row processing is arbitrary, and the decoding processing is cyclically performed again from the starting column after the processing is completed through the last column.

$$[ Numerical Expression 14 ]$$

$$\begin{matrix}{α}_{mn}^{( 1 )} = {\prod }_{{{n}^{′} ∈ N ( m ) \backslash n}_{{n}^{′} < g \cdot {N}_{G}}} sgn ( {β}_{{mn}^{′}}^{( 1 )} ) \cdot {\prod }_{{{n}^{′} ∈ N ( m ) \backslash n}_{{n}^{′} > g \cdot {N}_{G}}} sgn ( {β}_{{mn}^{′}}^{( 1 - 1 )} ) \cdot {min}_{{n}^{′} ∈ {N}_{k} ( m ) \backslash n} [ {B}_{{mn}^{′}}^{C} ] \\ = {S}_{m} \cdot sgn ( {β}_{mn}^{( 1 - 1 )} ) \cdot {min}_{{n}^{′} ∈ {N}_{k} ( m ) \backslash n} [ {B}_{{mn}^{′}}^{C} ] \\ = {S}_{m}^{′} \cdot {min}_{{n}^{′} ∈ {N}_{k} ( m ) \backslash n} [ {B}_{{mn}^{′}}^{C} ] \\ {S}_{m}^{′} = {S}_{m} \cdot sgn ( {β}_{mn}^{( 1 - 1 )} )\end{matrix} \qquad ( 21 )$$

Specifically, columns are divided into G column groups for each number of columns: N_{G}, and G row processing units respectively assigned to the column groups perform the row processing in parallel.

(Column Processing Step)

Next, as the column processing, LLR: βₘₙ⁽¹⁾ of l-th repetition of the bit n to be transmitted from the bit node n to the check node m is updated by following Equation (22) for 0≦g≦G−1, g·N_{G}+1≦n≦(g+1)·N_{G}, and each m. Namely, in the present embodiment, the column processing shown in following Equation (22) is performed in parallel for each column after the row processing has been performed in parallel thereto as explained above.

$$[ Numerical Expression 15 ]$$

$${β}_{mn}^{( l )} = {λ}_{n} + {\sum }_{{m}^{′} ∈ M ( n ) \backslash m} {α}_{{m}^{′} n}^{( l )} \\ {S}_{m} = {S}_{m}^{′} \cdot sgn ( {β}_{mn}^{( l )} ) \\ n ( i ) = arg {min}_{{n}^{′} ∈ {N}_{k} ( m ) \backslash \{ n ( 1 ) , n ( 2 ) , … , n ( i - 1 ) , n ( i ) \}} [ {B}_{{mn}^{′}}^{C} , \vert {β}_{mn}^{( l )} \vert ] \\ {B}_{mn ( i )}^{C} = {min}_{{n}^{′} ∈ {N}_{k} ( m ) \backslash \{ n ( 1 ) , n ( 2 ) , … , n ( i - 1 ) , n ( i ) \}} [ {B}_{{mn}^{′}}^{C} , \vert {β}_{mn}^{( l )} \vert ] , ∀ i ∈ [ 1 , k ] \qquad ( 22 )$$

For each n, a posterior value βₙ^{(l)} of the l-th repetition of the bit n is updated by following Equation (23) for the hard decision.

$$[ Numerical Expression 16 ]$$

$${β}_{m}^{( l )} = {λ}_{n} + {\sum }_{{m}^{′} ∈ M ( n )} {α}_{n}^{( l )} \qquad ( 23 )$$

(Stopping Rule)

Thereafter, for example, the decoded result is set as “xₙ′=1” (x′ corresponds to an original transmission signal x) when the posterior value βₙ^{(l)} of the l-th repetition of the bit n is “βₙ^{(l)}>0”, whereas the decoded result is set as “xₙ′=0” when “βₙ^{(l)}≦0”, so that the decoded result x′=(x₁′, x₂′, . . . , x_{N}′) is obtained.

When the result of the parity check is “Hx′=0” or the repetition number of times is “l=lₘₐₓ” (when either of the conditions is satisfied), the decoded result x′ at that time is outputted. Here, if both of the conditions are not satisfied, then “l=l+1”, and the processing returns to the row processing to sequentially perform the operation.

Subsequently, a configuration and operation of the LDPC decoder 5 according to the fifth embodiment that achieves the “Overlapped cyclic approximation min algorithm” will be explained.

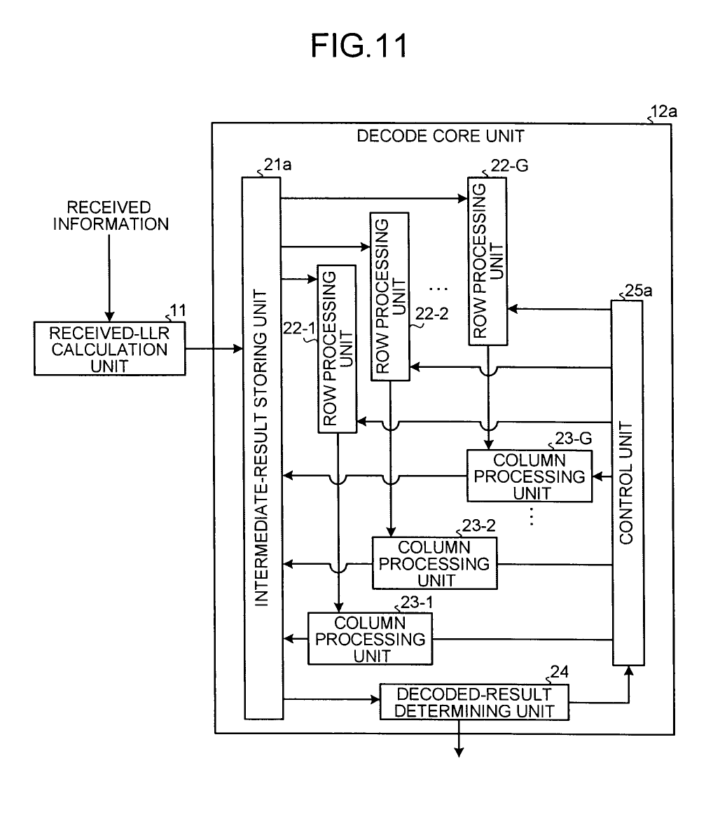

FIG. 11 is a schematic diagram illustrating a configuration example of the LDPC decoder 5 according to the present embodiment, wherein it is configured by the received-LLR calculation unit 11 for calculating received LLR from the received information and the decode core unit 12a for performing the decoding processing. The decode core unit 12a is provided with an intermediate-result storing unit 21a configured by a memory for holding the intermediate result of decoding (intermediate value), row processing units 22-1 to 22-G for executing row processing, column processing units 23-1 to 23-G for executing column processing, a decoded-result determining unit 24 for performing hard decision of a posterior value in the column processing and accuracy determination of the parity check result as a stopping rule of the decoding processing, and a control unit 25a for performing repetition control of decoding.

In FIG. 11, the LDPC decoder 5 according to the present embodiment commonly uses Bₘₙ^{C} and Sₘ in the intermediate-result storing unit 21a according to Equation (20), Equation (21), and Equation (22), and updates each of them when the respective row processing units and the respective column processing units perform processing in parallel. With this parallel processing, Bₘₙ^{C} and Sₘ, are rapidly updated depending on the number of parallelization, and thereby the repetition number of times of decoding can be greatly reduced.

Subsequently, an effect of using the “Overlapped cyclic approximation min algorithm”, for example, as the decoding processing for the codes configured in the processing of the first to fourth embodiments will be explained.

For example, in a case where a problem occurs that the operation of the same row at the same clock occurs and the same buffer is referenced in the parallel processing as explained above, an approach with an additional circuit is conventionally required. It is applicable not only to the “Overlapped cyclic approximation min algorithm” but also to any other decoding methods.

To solve this problem, in the present embodiment, characteristics of the parity check matrix generated by masking the quasi-cyclic matrix composed of p-row×p-column cyclic permutation matrix are utilized to divide the column group for the parallel processing into G1=[0*p+1, 1*p+1, 2*p+1, . . . ], G2=[0*p+2, 1*p+2, 2*p+2, . . . ], G3=[0*p+3, 1*p+3, 2*p+3, . . . ], . . . , when performing the parallel processing in the decoding to avoid the occurrence of overlapping of the rows and the columns, and to perform the processing of all or part of the groups in parallel from the minimum value of elements in each group.

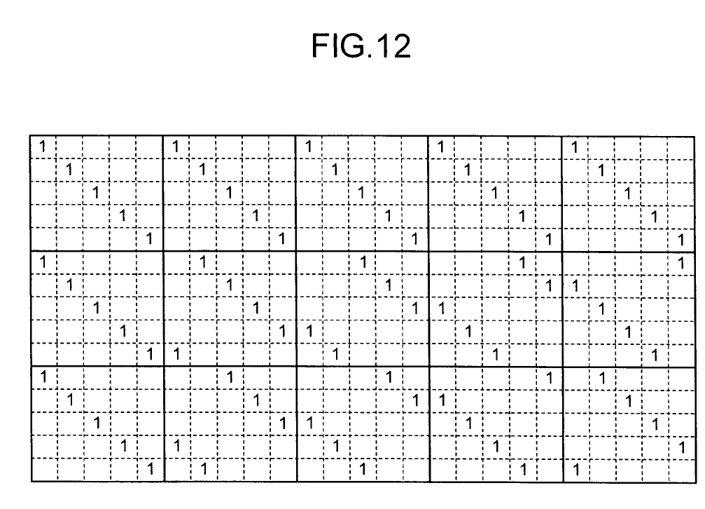

In the decoding processing of a specific column group, the rows related to the column are processed in parallel. For example, in a case of the quasi-cyclic code shown in FIG. 12 explained above, it is divided into G1=[1, 6, 11, 16, 21], G2=[2, 7, 12, 17, 22], G3=[3, 8, 13, 18, 23], G4=[4, 9, 14, 19, 24], and G5=[5, 10, 15, 20, 25]. Here, while processing G1, G2, G3, G4, G5 in parallel, the first element column in each group, 1, 2, 3, 4, and 5, are processed in parallel, and the elements of the next column, 6, 7, 8, 9, and 10, are then processed, so that the columns are not overlapped. The column index of the first element in G1 is 1 and the row indexes related thereto are 1, 6, and 11, so that these three rows can be processed in parallel. At the same time, the column index of the first element in G2 is 2 and the row indexes related thereto are 2, 7, and 12, so that these three rows can also be processed in parallel and are not overlapped with the row index processed in G1. Similarly, the rows and the columns are not overlapped in all the groups, so that the parallel processing without overlapping can be performed by grouping as explained above without a particular additional circuit.

When an irregular masking quasi-cyclic matrix is used, a difference between processing times may occur in a high weight portion and a low weight portion of the column processing. Generally, if there is a mixture of the heavy column degree and the light column degree in the irregular LDPC codes, a problem arises that the column processing in the heavy column degree becomes dominant and this interferes with speeding up of the processing.

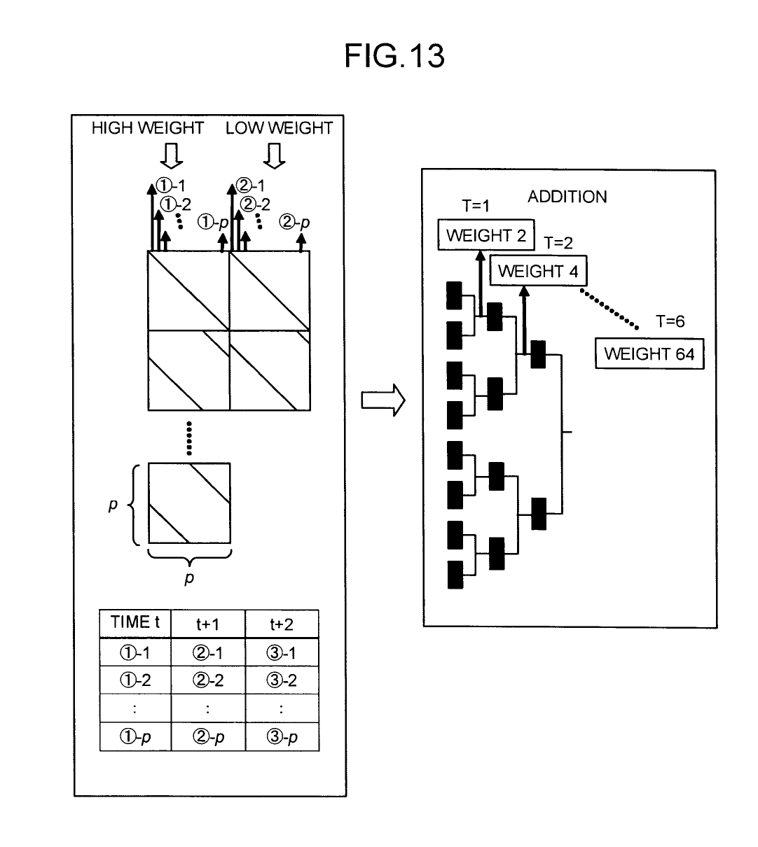

For example, as shown in FIG. 13, if the parallelizing processing is performed on the QC-LDPC codes by each size p of cyclic permutation matrices, all the codes have the same column degree in the range, so that all the p processing times required for addition processing (which corresponds to “addition” in FIG. 15) in the column processing correspond to one another. Moreover, the rows do not correspond to each other, and thus conflict avoidance processing for the row processing is not required. As for timing of addition in a tournament system of shared addition circuits, solutions are obtained at timing T=1, 2, 3, 4, 5, and 6 in column degree 2 or less, 2 to 3, 4 to 7, 8 to 15, 16 to 31, and 32 to 63, respectively. Because of this, if the timing of obtaining solutions is controlled to perform processing on a cyclic matrix basis, timing loss does not occur. Namely, it is only necessary to obtain each output time of the solution according to the column weight and to perform the next column processing when it reaches the timing in which the solution is obtained. The problem that the column processing in the portion with the heavy column degree becomes dominant can be avoided by the method.

The parallelizing processing of the “Overlapped cyclic approximation min algorithm” is described in the present embodiment, however, it is not limited thereby, and thus, if the system is any one in which encoding is performed using a parity check matrix generated by masking the quasi-cyclic matrix formed of the cyclic permutation matrices, the present embodiment is also applicable to a case where any other LDPC decoding method is processed in parallel.

### Sixth Embodiment

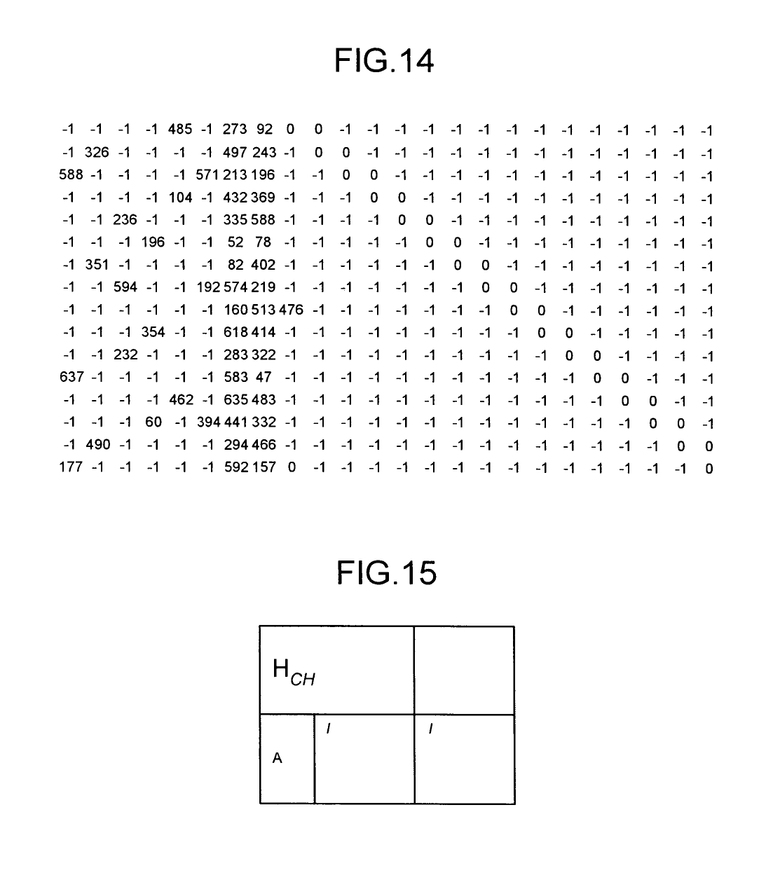

The first embodiment shows the example of forming the cyclic permutation matrices I(p_{j,l}) based on the fixed rule, however, the first embodiment may be applied to other matrices, and thus, in the present embodiment, the encoding rate ⅕ may be formed as is the first embodiment using the matrix of the encoding rate ⅓ as shown in FIG. 14 which is open to public (ZTE et al, “Comparison of structured LDPC Codes and 3GPP Turbo codes”, 3GPP TSG RAN WG1 #43, R1-051360, Seoul, Korea 7th-11th, Nov. 2005). Note that numerals in FIG. 14 represent values of p_{j,l}, and −1 means a zero-matrix of p×p.

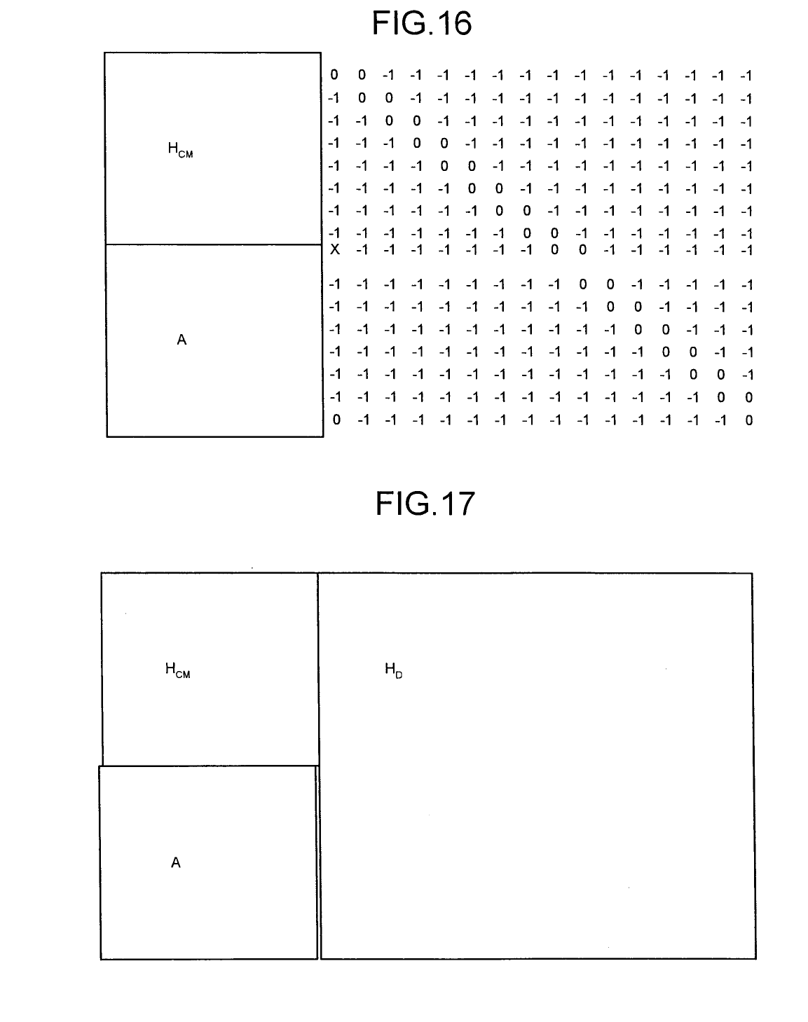

Specifically, supposing the matrix shown in FIG. 14 is a M×N matrix H_{CH} of the encoding rate ⅓, a matrix H_{CH}′ of 2M×( 5/3)N is formed as shown in FIG. 15, in which A is formed of matrices based on a combination of cyclic permutation matrices, and two unit matrices I are arranged in the lower right side of FIG. 15 so as to be coupled to each other. A weight distribution of the matrix A is derived by a density evolution method. The parity check matrix for LDPC can be generated by this method similarly to the first embodiment. Moreover, the matrix may also be configured as shown in FIG. 16. A matrix H_{CM}′ of 2M×3M is configured as shown in FIG. 16 by a matrix H_{CM} of M×M and the matrix A of M×M based on a combination of the cyclic permutation matrices and zero-matrices. The weight distribution of the matrix H_{CM} and the matrix A is derived by the density evolution method. The matrix on the right-hand side is configured in a similar manner to the matrix on the right-hand side of FIG. 14. Note that a numerical value of X in the matrix is an arbitrary value. RC-LDPC codes can be formed by using this method. Alternatively, the codes may be configured as shown in FIG. 17. The matrix H_{CM}′ of 2M×3M is configured as shown in FIG. 17 by the matrix H_{CM} of M×M and the matrix A of M×M based on the combination of the cyclic permutation matrices and the zero-matrices. The weight distribution of the matrix H_{CM} and the matrix A is derived by the density evolution method. The Equation (5-2) is used for the matrix on the right-hand side. The RC-LDPC codes can be formed by using this method.

It is noted that the matrix A may be configured with matrices based on an arbitrary combination of the cyclic permutation matrices as shown in the present embodiment, or may be configured based on the regular rule as shown in the first embodiment. The processing of forming the LDPC codes corresponding to the encoding rates is not limited to the parity check matrix as shown in FIG. 14, but is applicable to any type of parity check matrix.

### Seventh Embodiment

Next, the system to which the encoding processing/decoding processing according to the first to the sixth embodiments is applied will be explained. For example, the LDPC encoding processing and decoding processing according to the present invention are applicable to communications equipment in general, such as mobile communications (terminal, base station), wireless LAN, optical communications, satellite communications, and a quantum encryption device, and specifically, the LDPC encoder 1 and the LDPC decoder 5 as shown in FIG. 1 are incorporated in each communications equipment to perform the error correction.

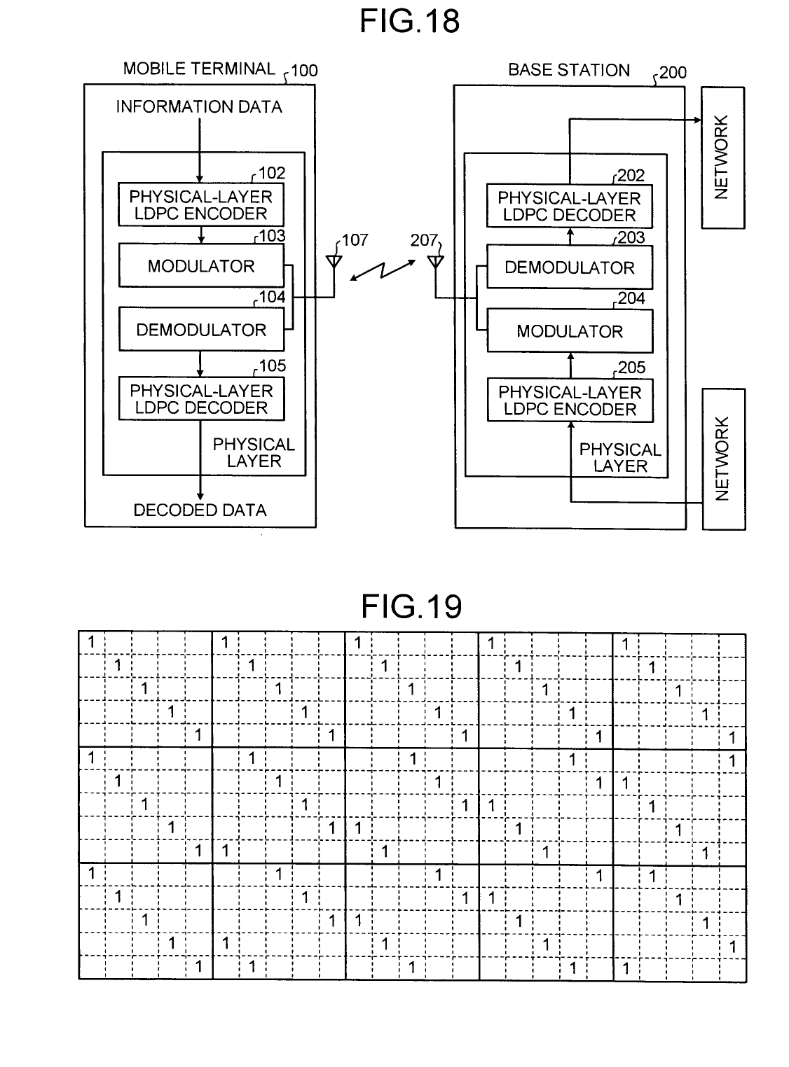

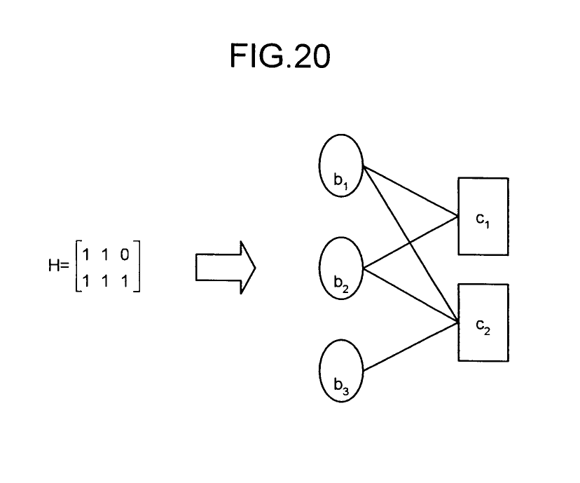

FIG. 18 is a schematic diagram illustrating a configuration example when the encoding processing/decoding processing according to the present invention is applied to a mobile communications system provided with a mobile terminal 100 and a base station 200 that communicates with the mobile terminal 100, wherein the mobile terminal 100 includes a physical-layer LDPC encoder 102, a modulator 103, a demodulator 104, a physical-layer LDPC decoder 105, and an antenna 107, while the base station 200 includes a physical-layer LDPC decoder 202, a demodulator 203, a modulator 204, a physical-layer LDPC encoder 205, and an antenna 207.

Moreover, in the mobile terminal 100 and the base station 200 shown in FIG. 18, the physical-layer LDPC encoder 102 and the physical-layer LDPC decoder 105 applied to fading communication channels or the like are incorporated in the physical layers, respectively.

Incidentally, one of the configurations of the LPDC encoders explained in the first to the sixth embodiments is applied to the physical-layer LDPC encoders for the mobile terminal 100 and the base station 200. Meanwhile, one of the configurations of the LDPC decoders described in the first to the sixth embodiments is applied to the physical-layer LDPC decoders for the mobile terminal 100 and the base station 200.

When data is transmitted from the mobile terminal 100 in the mobile communications system composed as described above, first, in the physical layer, the physical-layer LDPC encoder 102 for fading communication channel encodes the data for each packet data. This encoded data is sent out to a radio communication channel via the modulator 103 and the antenna 107.

Meanwhile, in the base station 200, received signals including errors generated in the radio communication channel are received via the antenna 207 and the demodulator 203, and received data after demodulation is corrected by the physical-layer LDPC decoder 202 for the physical layer. Subsequently, this information packet is transmitted to a communication destination via the network. Note that also when the mobile terminal 100 receives various data from the network, the base station 200 transmits the encoded data to the mobile terminal 100, and the mobile terminal 100 reproduces the various data, by the processing similar to that described above. When the base station 200 transmits encoded data to the mobile terminal 100, first, in the physical layer, the physical-layer LDPC encoder 205 for fading communication channel encodes data for each packet data. This encoded data is sent out to the radio communication channel via the modulator 204 and the antenna 207. Meanwhile, in the mobile terminal 100, received signals including errors generated in the radio communication channel are received via the antenna 107 and the demodulator 104, the received data after demodulation is corrected by the physical layer LDPC decoder 105. In the physical layer, whether the error correction is successfully performed per packet is then notified to the upper layer.

### INDUSTRIAL APPLICABILITY

As described above, the check-matrix generating method and encoding method according to the present invention are useful as the encoding technology in digital communications, and are particularly suitable for the communication apparatuses that employ the LDPC codes as the encoding system.

1-10. (canceled)

11. A method of generating a parity check matrix for a low-density parity check code, the method comprising:
generating a regular quasi-cyclic matrix in which cyclic permutation matrices are arranged in a row direction and a column direction and specific regularity is given to the cyclic permutation matrices;
generating a mask matrix capable of supporting a plurality of encoding rates, for making the regular quasi-cyclic matrix into an irregular quasi-cyclic matrix;
masking including generating an irregular masked quasi-cyclic matrix by converting a specific cyclic permutation matrix in the regular quasi-cyclic matrix into a zero-matrix using a mask matrix supporting a specific encoding rate; and
generating an irregular parity check matrix with a low-density generation matrix structure in which a masked quasi-cyclic matrix and a matrix in which the cyclic permutation matrices are arranged in a staircase manner are arranged in predetermined positions, wherein
the specific regularity is such that “p_{j,l}=(((p_{A}−p_{0,1})(j+1))mod p_{A})mod p” is provided to p_{j,l} of cyclic permutation matrices I(p_{j,l}) with p-row×p-column arranged at a row index j (0≦j≦J−1) and a column index l (0≦l≦L−1), where I(p_{j,l}) are cyclic permutation matrices in which positions of a row index r (0≦r≦p−1) and a column index “(r+p_{j,l})mod p” are “1” and other positions are “0”.

12. A communication apparatus that generates a parity check matrix for a low-density parity check code, the communication apparatus comprising:
a regular quasi-cyclic matrix generating unit that generates a regular quasi-cyclic matrix in which cyclic permutation matrices are arranged in a row direction and a column direction and specific regularity is given to the cyclic permutation matrices;
a mask matrix generating unit that generates a mask matrix capable of supporting a plurality of encoding rates, for making the regular quasi-cyclic matrix into an irregular quasi-cyclic matrix;
a masking unit that generates an irregular masked quasi-cyclic matrix by converting a specific cyclic permutation matrix in the regular quasi-cyclic matrix into a zero-matrix using a mask matrix supporting a specific encoding rate; and
an irregular parity check matrix generating unit that generates an irregular parity check matrix with a low-density generation matrix structure in which a masked quasi-cyclic matrix and a matrix in which the cyclic permutation matrices are arranged in a staircase manner are arranged in predetermined positions, wherein
the specific regularity is such that “p_{j,l}=(((p_{A}−p_{0,1})(j+1))mod p_{A})mod p” is provided to p_{j,l} of cyclic permutation matrices I(p_{j,l}) with p-row×p-column arranged at a row index j (0≦j≦J−1) and a column index l (0≦l≦L−1), where I(p_{j,l}) are cyclic permutation matrices in which positions of a row index r (0≦r≦p−1) and a column index “(r+p_{j,l})mod p” are “1” and other positions are “0”.

13. A method of generating a parity check matrix when supporting a plurality of encoding rates using a known irregular parity check matrix for a low-density parity check code, the method comprising:
generating a parity check matrix supporting a desired encoding rate by executing a density evolution method with a column degree distribution of the known irregular parity check matrix as a restriction condition and coupling a matrix generated based on the column degree distribution obtained by executing the density evolution method to the known irregular parity check matrix.

14. A communication apparatus that generates a parity check matrix when supporting a plurality of encoding rates using a known irregular parity check matrix for a low-density parity check code, the communication apparatus comprising:
a parity check matrix generating unit that generates a parity check matrix supporting a desired encoding rate by executing a density evolution method with a column degree distribution of the known irregular parity check matrix as a restriction condition and coupling a matrix generated based on the column degree distribution obtained by executing the density evolution method to the known irregular parity check matrix.

15. A method of encoding predetermined data bits using a parity check matrix for a low-density parity check code, the method comprising:
generating a regular quasi-cyclic matrix in which cyclic permutation matrices of p-row×p-column are arranged in a row direction and a column direction and specific regularity is given to the cyclic permutation matrices;
generating a mask matrix capable of supporting a plurality of encoding rates, for making the regular quasi-cyclic matrix into an irregular quasi-cyclic matrix;
masking including generating an irregular masked quasi-cyclic matrix by converting a specific cyclic permutation matrix in the regular quasi-cyclic matrix into a zero-matrix using a mask matrix supporting a specific encoding rate;
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
encoding predetermined data bits using the irregular parity check matrix generated at the generating an irregular parity check matrix, wherein
the encoding includes
selecting an integer value obtained by rounding up “data length K/number r of cyclic permutation matrices” for p, and
inserting sequentially known values of a number of “p×r−K” in bits corresponding to a portion with a light column degree in a data bit portion in the irregular parity check matrix.

16. A method of decoding data bits that are encoded on a transmission side using a parity check matrix for a low-density parity check code, wherein
the data bits are encoded by
generating a regular quasi-cyclic matrix in which cyclic permutation matrices of p-row×p-column are arranged in a row direction and a column direction and specific regularity is given to the cyclic permutation matrices,
generating a mask matrix capable of supporting a plurality of encoding rates, for making the regular quasi-cyclic matrix into an irregular quasi-cyclic matrix,
masking including generating an irregular masked quasi-cyclic matrix by converting a specific cyclic permutation matrix in the regular quasi-cyclic matrix into a zero-matrix using a mask matrix supporting a specific encoding rate,
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
encoding predetermined data bits using the irregular parity check matrix generated at the generating an irregular parity check matrix, wherein the encoding includes selecting an integer value obtained by rounding up “data length K/number r of cyclic permutation matrices” for p and inserting sequentially known values of a number of “p×r−K” in bits corresponding to a portion with a light column degree in a data bit portion in the irregular parity check matrix, and
the method comprises decoding including a reception side decoding the data bits by determining a known value for a value corresponding to a same bit of the parity check matrix.

17. An encoder that encodes predetermined data bits using a parity check matrix for a low-density parity check code, the encoder comprising:
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices;
a mask matrix generating unit that generates a mask matrix capable of supporting a plurality of encoding rates, for making the regular quasi-cyclic matrix into an irregular quasi-cyclic matrix;
a masking unit that generates an irregular masked quasi-cyclic matrix by converting a specific cyclic permutation matrix in the regular quasi-cyclic matrix into a zero-matrix using a mask matrix supporting a specific encoding rate;
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
an encoding unit that encodes predetermined data bits using the irregular parity check matrix generated by the irregular parity check matrix generating unit, wherein
the encoding unit selects an integer value obtained by rounding up “data length K/number r of cyclic permutation matrices” for p, and sequentially inserts known values of a number of “p×r−K” in bits corresponding to a portion with a light column degree in a data bit portion in the irregular parity check matrix.

18. A decoder that decodes data bits that are encoded by an encoder that encodes predetermined data bits using a parity check matrix for a low-density parity check code, wherein
the encoder includes
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices,
a mask matrix generating unit that generates a mask matrix capable of supporting a plurality of encoding rates, for making the regular quasi-cyclic matrix into an irregular quasi-cyclic matrix,
a masking unit that generates an irregular masked quasi-cyclic matrix by converting a specific cyclic permutation matrix in the regular quasi-cyclic matrix into a zero-matrix using a mask matrix supporting a specific encoding rate,
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
an encoding unit that encodes predetermined data bits using the irregular parity check matrix generated by the irregular parity check matrix generating unit, wherein the encoding unit selects an integer value obtained by rounding up “data length K/number r of cyclic permutation matrices” for p, and sequentially inserts known values of a number of “p×r−K” in bits corresponding to a portion with a light column degree in a data bit portion in the irregular parity check matrix, and
the decoder comprises a decoding unit that decodes the data bits by determining a known value for a value corresponding to a same bit of the parity check matrix.

19. A method of encoding predetermined data bits using a parity check matrix for a low-density parity check code, the method comprising:
generating a regular quasi-cyclic matrix in which cyclic permutation matrices of p-row×p-column are arranged in a row direction and a column direction and specific regularity is given to the cyclic permutation matrices;
generating a mask matrix capable of supporting a plurality of encoding rates, for making the regular quasi-cyclic matrix into an irregular quasi-cyclic matrix;
masking including generating an irregular masked quasi-cyclic matrix by converting a specific cyclic permutation matrix in the regular quasi-cyclic matrix into a zero-matrix using a mask matrix supporting a specific encoding rate;
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
encoding predetermined data bits using the irregular parity check matrix generated at the generating an irregular parity check matrix, wherein
when realizing an encoding rate equal to or less than an encoding rate (N−M)/N that is decided by a number of rows M and a number of columns N of the irregular parity check matrix, the encoding includes inserting sequentially known values in bits corresponding to a portion with a light column degree in a data bit portion in the irregular parity check matrix.

20. A method of decoding data bits that are encoded on a transmission side using a parity check matrix for a low-density parity check code, wherein
the data bits are encoded by
generating a regular quasi-cyclic matrix in which cyclic permutation matrices of p-row×p-column are arranged in a row direction and a column direction and specific regularity is given to the cyclic permutation matrices,
generating a mask matrix capable of supporting a plurality of encoding rates, for making the regular quasi-cyclic matrix into an irregular quasi-cyclic matrix,
masking including generating an irregular masked quasi-cyclic matrix by converting a specific cyclic permutation matrix in the regular quasi-cyclic matrix into a zero-matrix using a mask matrix supporting a specific encoding rate,
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
encoding predetermined data bits using the irregular parity check matrix generated at the generating an irregular parity check matrix, wherein when realizing an encoding rate equal to or less than an encoding rate (N−M)/N that is decided by a number of rows M and a number of columns N of the irregular parity check matrix, the encoding includes inserting sequentially known values in bits corresponding to a portion with a light column degree in a data bit portion in the irregular parity check matrix, and
the method comprises decoding including a reception side decoding the data bits by determining a known value for a value corresponding to a same bit of the parity check matrix.

21. An encoder that encodes predetermined data bits using a parity check matrix for a low-density parity check code, the encoder comprising:
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices;
a mask matrix generating unit that generates a mask matrix capable of supporting a plurality of encoding rates, for making the regular quasi-cyclic matrix into an irregular quasi-cyclic matrix;
a masking unit that generates an irregular masked quasi-cyclic matrix by converting a specific cyclic permutation matrix in the regular quasi-cyclic matrix into a zero-matrix using a mask matrix supporting a specific encoding rate;
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
an encoding unit that encodes predetermined data bits using the irregular parity check matrix generated by the irregular parity check matrix generating unit, wherein
when realizing an encoding rate equal to or less than an encoding rate (N−M)/N that is decided by a number of rows M and a number of columns N of the irregular parity check matrix, the encoding unit sequentially inserts known values in bits corresponding to a portion with a light column degree in a data bit portion in the irregular parity check matrix.

22. A decoder that decodes data bits that are encoded by an encoder that encodes predetermined data bits using a parity check matrix for a low-density parity check code, wherein
the encoder includes
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices,
a mask matrix generating unit that generates a mask matrix capable of supporting a plurality of encoding rates, for making the regular quasi-cyclic matrix into an irregular quasi-cyclic matrix,
a masking unit that generates an irregular masked quasi-cyclic matrix by converting a specific cyclic permutation matrix in the regular quasi-cyclic matrix into a zero-matrix using a mask matrix supporting a specific encoding rate,
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
an encoding unit that encodes predetermined data bits using the irregular parity check matrix generated by the irregular parity check matrix generating unit, wherein when realizing an encoding rate equal to or less than an encoding rate (N−M)/N that is decided by a number of rows M and a number of columns N of the irregular parity check matrix, the encoding unit sequentially inserts known values in bits corresponding to a portion with a light column degree in a data bit portion in the irregular parity check matrix, and
the decoder comprises a decoding unit that decodes the data bits by determining a known value for a value corresponding to a same bit of the parity check matrix.

23. A method of encoding predetermined data bits using a parity check matrix for a low-density parity check code, the method comprising:
generating a regular quasi-cyclic matrix in which cyclic permutation matrices of p-row×p-column are arranged in a row direction and a column direction and specific regularity is given to the cyclic permutation matrices;
generating a mask matrix capable of supporting a plurality of encoding rates, for making the regular quasi-cyclic matrix into an irregular quasi-cyclic matrix;
masking including generating an irregular masked quasi-cyclic matrix by converting a specific cyclic permutation matrix in the regular quasi-cyclic matrix into a zero-matrix using a mask matrix supporting a specific encoding rate;
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
encoding predetermined data bits using the irregular parity check matrix generated at the generating an irregular parity check matrix, wherein
the encoding includes
selecting an integer value obtained by rounding up “data length K/number r of cyclic permutation matrices” for p, and
inserting known values of a number of “p×r−K” in a data bit portion in the irregular parity check matrix at virtually uniform intervals.

24. A method of decoding data bits that are encoded on a transmission side using a parity check matrix for a low-density parity check code, wherein
the data bits are encoded by
generating a regular quasi-cyclic matrix in which cyclic permutation matrices of p-row×p-column are arranged in a row direction and a column direction and specific regularity is given to the cyclic permutation matrices,
generating a mask matrix capable of supporting a plurality of encoding rates, for making the regular quasi-cyclic matrix into an irregular quasi-cyclic matrix,
masking including generating an irregular masked quasi-cyclic matrix by converting a specific cyclic permutation matrix in the regular quasi-cyclic matrix into a zero-matrix using a mask matrix supporting a specific encoding rate,
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
encoding predetermined data bits using the irregular parity check matrix generated at the generating an irregular parity check matrix, wherein the encoding includes selecting an integer value obtained by rounding up “data length K/number r of cyclic permutation matrices” for p and inserting known values of a number of “p×r−K” in a data bit portion in the irregular parity check matrix at virtually uniform intervals, and
the method comprises decoding including a reception side decoding the data bits by determining a known value for a value corresponding to a same bit of the parity check matrix.

25. An encoder that encodes predetermined data bits using a parity check matrix for a low-density parity check code, the encoder comprising:
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices;
a mask matrix generating unit that generates a mask matrix capable of supporting a plurality of encoding rates, for making the regular quasi-cyclic matrix into an irregular quasi-cyclic matrix;
a masking unit that generates an irregular masked quasi-cyclic matrix by converting a specific cyclic permutation matrix in the regular quasi-cyclic matrix into a zero-matrix using a mask matrix supporting a specific encoding rate;
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions; and
an encoding unit that encodes predetermined data bits using the irregular parity check matrix generated by the irregular parity check matrix generating unit, wherein
the encoding unit selects an integer value obtained by rounding up “data length K/number r of cyclic permutation matrices” for p, and inserts known values of a number of “p×r−K” in a data bit portion in the irregular parity check matrix at virtually uniform intervals.

26. A decoder that decodes data bits that are encoded by an encoder that encodes predetermined data bits using a parity check matrix for a low-density parity check code, wherein
the encoder includes
a regular quasi-cyclic matrix generating unit that generates a regular quasi-cyclic matrix in which cyclic permutation matrices of p-row×p-column are arranged in a row direction and a column direction and specific regularity is given to the cyclic permutation matrices,
a mask matrix generating unit that generates a mask matrix capable of supporting a plurality of encoding rates, for making the regular quasi-cyclic matrix into an irregular quasi-cyclic matrix,
a masking unit that generates an irregular masked quasi-cyclic matrix by converting a specific cyclic permutation matrix in the regular quasi-cyclic matrix into a zero-matrix using a mask matrix supporting a specific encoding rate,
an irregular parity check matrix generating unit that generates an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
an encoding unit that encodes predetermined data bits using the irregular parity check matrix generated by the irregular parity check matrix generating unit, wherein the encoding unit selects an integer value obtained by rounding up “data length K/number r of cyclic permutation matrices” for p, and inserts known values of a number of “p×r−K” in a data bit portion in the irregular parity check matrix at virtually uniform intervals, and
the decoder comprises a decoding unit that decodes the data bits by determining a known value for a value corresponding to a same bit of the parity check matrix.

27. A method of decoding data bits that are encoded on a transmission side using a parity check matrix for a low-density parity check code, wherein
the data bits are encoded by
generating a regular quasi-cyclic matrix in which cyclic permutation matrices of p-row×p-column are arranged in a row direction and a column direction and specific regularity is given to the cyclic permutation matrices,
generating a mask matrix capable of supporting a plurality of encoding rates, for making the regular quasi-cyclic matrix into an irregular quasi-cyclic matrix,
masking including generating an irregular masked quasi-cyclic matrix by converting a specific cyclic permutation matrix in the regular quasi-cyclic matrix into a zero-matrix using a mask matrix supporting a specific encoding rate,
generating an irregular parity check matrix with a low-density generation matrix structure for a low-density parity check code in which the masked quasi-cyclic matrix and a matrix in which the cyclic permutation matrices are arranged in a staircase manner are arranged in predetermined positions, and
encoding predetermined data bits using the irregular parity check matrix generated at the generating an irregular parity check matrix, wherein the encoding includes selecting an integer value obtained by rounding up “data length K/number r of cyclic permutation matrices” for p and inserting sequentially known values of a number of “p×r−K” in bits corresponding to a portion with a light column degree in a data bit portion in the irregular parity check matrix, and
the method comprises, when a decoding process is performed on a reception side by executing a known overlapped cyclic approximation min algorithm determining including a decoder on the reception side determining a process time for an addition processing, which is a parallel processing, in a column processing and performing a next column processing upon reaching a timing at which a solution is obtained.
